(19) United States
(12) Patent Application Publication
(10) Pub. No.: US 2009/0020828 A1
(43) Pub. Date: Jan. 22, 2009

(54) SEMICONDUCTOR DEVICE AND ITS MANUFACTURING METHOD

(76) Inventor: Takayuki YAMADA, Osaka (JP)

Correspondence Address: MCDERMOTT WILL & EMERY LLP, 600 13TH STREET, NW, WASHINGTON, DC, 20005-3096, US

(21) Appl. No.: 12/172,372

(22) Filed: Jul. 14, 2008

(30) Foreign Application Priority Data
Jul. 19, 2007 (JP) 2007-188510

(51) Int. Cl. H01L 27/06; H01L 21/8234

(52) U.S. Cl. 257/379; 438/238; 257/E27.016; 257/E21.616

(57) ABSTRACT

A first MIS transistor includes a first source/drain region formed outside a first sidewall spacer in a first active region, a first silicide film formed on the first source/drain region, and a stressor insulating film formed on a first gate electrode, the first sidewall spacer, and the first silicide film. A second MIS transistor includes a second source/drain region formed outside a second sidewall spacer in a second active region, a first protection film formed, extending over a second gate electrode, the second sidewall spacer, and a portion of the second source/drain region, and including a first protection insulating film and a second protection insulating film, a second silicide film formed outside the first protection film on the second source/drain region, and the stressor insulating film formed on the first protection film and the second silicide film.

### CROSS REFERENCE TO RELATED APPLICATIONS

This Non-provisional application claims priority under 35 U.S.C. §119(a) on Patent Application No. 2007-188510 filed in Japan on Jul. 19, 2007, the entire contents of which are hereby incorporated by reference.

### BACKGROUND OF THE INVENTION

1. Field of the Invention

The present invention relates to a semiconductor device and its manufacturing method. More particularly, the present invention relates to a semiconductor device comprising a transistor having a silicide film on a source/drain region and a method for manufacturing the device.

2. Description of the Related Art

In recent years, there is a demand for a semiconductor integrated circuit that simultaneously achieves high speed and low power consumption. To meet the demand, it is necessary to simultaneously achieve an improvement in drive capability and a reduction in leakage current of a transistor.

In order to improve the drive capability of a transistor, a parasitic resistance may be reduced by forming a silicide film on a gate and a source/drain region, and the mobility of carriers in a channel may be improved by applying a stress to the transistor. A method for applying a stress to a transistor has been proposed in which, after removal of a sidewall spacer, a stressor insulating film is formed to cover a gate electrode (see, for example, Patent Document 1: Japanese Unexamined Patent Application Publication No. 2007-49166). Here, in the case of a gate electrode included in an N-type transistor, a stressor insulating film is formed which generates a tensile stress in a gate length direction in the channel of the N-type transistor. On the other hand, in the case of a gate electrode included in a P-type transistor, a stressor insulating film is formed which generates a compressive stress in a gate length direction in the channel of the P-type transistor.

On the other hand, in addition to a transistor for which an improvement in drive capability is required, a semiconductor integrated circuit needs to carry a transistor used in, for example, an ESD protection device or the like, and a resistance device having a resistor made of the same material as that of the gate electrodes of these transistors.

Hereinafter, a method for manufacturing a semiconductor device comprising a transistor for which an improvement in drive capability is required (hereinafter referred to as a first MIS transistor), a transistor that is used in, for example, an ESD protection device or the like (hereinafter referred to as a second MIS transistor), and a resistance device having a resistor made of the same materials as that of the gate electrodes of the first and second MIS transistors, will be described with reference to FIGS. 9A to 9C, FIGS. 10A and 10B, FIGS. 11A and 11B, and FIGS. 12A and 12B. FIGS. 9A to 9C, FIGS. 10A and 10B, FIGS. 11A and 11B, and FIGS. 12A and 12B are cross-sectional views showing major steps of a method for manufacturing a conventional semiconductor device, in the order in which the steps are to be performed. Note that, in each of the figures, a first MIS transistor formation region A is shown on a left-hand side thereof, a second MIS transistor formation region B is shown in a middle thereof, and a resistance device formation region C is shown on a right-hand side thereof.

Initially, as shown in FIG. 9A, an isolation region 401 in which a silicon oxide film is buried in a trench is selectively formed in an upper portion of a semiconductor substrate 400 made of silicon by Shallow Trench Isolation (STI). Thereby, a first active region 400a made of the semiconductor substrate 400 surrounded by the isolation region 401 is formed in the first MIS transistor formation region A, and a second active region 400b made of the semiconductor substrate 400 surrounded by the isolation region 401 is formed in the second MIS transistor formation region B.

Next, a gate insulating film formation film made of a silicon oxide film (or a silicon oxynitride film) is formed on the first and second active regions 400a and 400b, and thereafter, a gate electrode formation film made of a silicon film is formed on the semiconductor substrate 400. Thereafter, the gate electrode formation film and the gate insulating film formation film on the first and second active regions 400a and 400b are subjected to patterning to form a first and a second gate insulating film 402a and 402b made of the gate insulating film formation film, and a first and a second gate electrode 403a and 403b made of the gate electrode formation film. Also, the gate electrode formation film on the isolation region 401 in the resistance device formation region C is subjected to patterning to form a resistor 403c made of the gate electrode formation film.

Thus, as shown in FIG. 9A, the first and second gate electrodes 403a and 403b made of a silicon film are formed via the first and second gate insulating films 402a and 402b made of a silicon oxide film (or a silicon oxynitride film) on the first and second active regions 400a and 400b, and the resistor 403c made of the same material as that of the first and second gate electrodes 403a and 403b is formed on the isolation region 401 in the resistance device formation region C.

Next, as shown in FIG. 9B, arsenic (As) is implanted into the first and second active regions 400a and 400b with an energy of 2 keV using the first and second gate electrodes 403a and 403b as a mask, thereby forming a first and a second extension region 404a and 404b in a self-alignment manner outside the first and second gate electrodes 403a and 403b in the first and second active regions 400a and 400b.

Next, as shown in FIG. 9C, a first insulating film made of a silicon oxide film having a film thickness of 10 nm and a second insulating film made of a silicon nitride film having a film thickness of 40 nm are deposited on an entire surface of the semiconductor substrate 400, covering the first and second gate electrodes 403a and 403b and the resistor 403c, and thereafter, anisotropic dry etching is performed with respect to the first and second insulating films. Thereby, a first and a second sidewall spacer 407a and 407b including first insulating films 405a and 405b having an L-shaped cross-section and second insulating films 406a and 406b are formed on side surfaces of the first and second gate electrodes 403a and 403b, and a third sidewall spacer 407c including a first insulating film 405c having an L-shaped cross-section and a second insulating film 406c is formed on a side surface of the resistor 403c.

Next, as shown in FIG. 10A, arsenic (As) is implanted into the first and second active regions 400a and 400b with an energy of 15 keV, using the first and second gate electrodes 403a and 403b and the first and second sidewall spacers 407a and 407b as a mask, thereby forming a first and a second source/drain region 408a and 408b outside the first and second sidewall spacers 407a and 407b in the first and second active regions 400a and 400b. Thereafter, the impurity contained in the first and second source/drain regions 408a and 408b is activated by a heat treatment at 1050° C.

Next, as shown in FIG. 10B, a protection film 409 made of a silicon oxide film having a film thickness of 30 nm is deposited on an entire surface of the semiconductor substrate 400 by CVD.

Next, as shown in FIG. 11A, a resist film r3 is formed on a portion of the protection film 409 that is formed on a portion of the second gate electrode 403b, the second sidewall spacer 407b, and the second source/drain region 408b, and a resist film r4 is formed on a portion of the protection film 409 that is formed on the resistor 403c and the third sidewall spacer 407c. Thereafter, portions other than portions formed below the resist films r3 and r4 of the protection film 409 are removed by wet etching with hydrogen fluoride, using the resist films r3 and r4 as a mask, so that a first protection film 409b made of the protection film is formed on the second gate electrode 403b, the second sidewall spacer 407b, and a portion of the second source/drain region 408b, and a second protection film 409c made of the protection film is formed on the resistor 403c and the third sidewall spacer 407c. In this case, conditions for wet etching are set so as to perform over-etching, taking into consideration variations in film thickness of the protection film 409 and variations in etching rate of wet etching. Specifically, for example, when the protection film 409 made of a silicon oxide film has a film thickness of 30 nm, conditions for wet etching are set so that the silicon oxide film will be removed by 36 nm.

Next, as shown in FIG. 11B, after the resist films r3 and r4 are removed, a metal film (not shown) made of a Ni film having a thickness of 10 nm is deposited on an entire surface of the semiconductor substrate 400 by sputtering, and thereafter, a heat treatment is performed to cause reaction of Si contained in the first and second source/drain regions 408a and 408b and the first gate electrode 403a and Ni contained in the metal film. Thus, by causing reaction of an upper portion of the first source/drain region 408a and the metal film, a first silicide film 412a made of a NiSi film having a film thickness of 20 nm is formed outside the first insulating film 405a on the first source/drain region 408a, and by causing reaction of an upper portion of the first gate electrode 403a and the metal film, an on-gate silicide film 413a made of a NiSi film having a film thickness of 20 nm is formed on the first gate electrode 403a. On the other hand, by causing reaction of an upper portion of the second source/drain region 408b and the metal film, a second silicide film 412b made of a NiSi film having a film thickness of 20 nm is formed outside the first protection film 409b on the second source/drain region 408b. Thereafter, an unreacted metal film remaining on the semiconductor substrate 400 is removed by etching.

Next, as shown in FIG. 12A, the second insulating film 406a of the first sidewall spacer 407a is removed by anisotropic dry etching, or wet etching with hot phosphoric acid, using the first and second protection films 409b and 409c and the isolation region 401, and the first and second silicide films 412a and 412b and the on-gate silicide film 413a, as a mask.

Next, as shown in FIG. 12B, a stressor insulating film 414 that generates a tensile stress in a gate length direction in the first active region 400a is formed on an entire surface of the semiconductor substrate 400.

Thereafter, as in a method for manufacturing a typical semiconductor device having a MIS transistor, an inter-layer insulating film 415 is deposited on the stressor insulating film 414 by CVD, and thereafter, a first and a second contact plug 416a and 416b that are connected to the first and second silicide films 412a and 412b are formed in the stressor insulating film 414 and the inter-layer insulating film 415. Thereafter, an inter-wiring insulating film 417 is formed on the inter-layer insulating film 415, and thereafter, a first and a second wiring 418a and 418b that are connected to the first and second contact plugs 416a and 416b are formed in the inter-wiring insulating film 417.

Thus, the conventional semiconductor device is manufactured.

However, the conventional semiconductor device manufacturing method has the following problems. The problems will be described with reference to FIGS. 13A and 13B. FIGS. 13A and 13B are cross-sectional views of major steps, indicating the problems with the conventional semiconductor device. Specifically, FIGS. 13A and 13B correspond to FIGS. 11A and 11B above, respectively.

In the conventional semiconductor device manufacturing method, when wet etching with hydrogen fluoride is performed with respect to the protection film (silicon oxide film) 409, the first insulating film (silicon oxide film) 405a and the isolation region (silicon oxide film) 401 are also subjected to wet etching. Therefore, as shown in FIG. 13A, a portion of the first insulating film 405a that is exposed on a surface is removed, so that an end portion of the first insulating film 405a is present further inside than a side surface of the second insulating film 406a to form a groove De. In addition, a portion of the isolation region 401 is removed, so that an upper surface of the isolation region 401 is lower than upper surfaces of the first and second source/drain regions 408a and 408b, resulting in a groove Ds. As a result, corner portions of the first and second source/drain regions 408a and 408b are exposed.

Therefore, in the next step that is a silicidation step, a heat treatment is performed in the first MIS transistor while the silicidation metal film is present inside the groove De. As a result, as shown in FIG. 13B, the first silicide film 412a is formed with an end thereof being present below the second insulating film 406a (see Sₑ). Therefore, a distance between a bottom surface of the first extension region 404a and the first silicide film 412a is so small that junction leakage occurs in the first extension region 404a. In addition, a heat treatment is performed while the silicidation metal film is in contact with the corner portion of the first source/drain region 408a, so that, as shown in FIG. 13B, the other end of the first silicide film 412a extends downward (see Sₛₐ). Therefore, a distance between a bottom surface of the first source/drain region 408a and the first silicide film 412a is so small that junction leakage occurs in the first source/drain region 408a.

A heat treatment is also performed in the second MIS transistor while the silicidation metal film is in contact with the corner portion of the second source/drain region 408b. As a result, as shown in FIG. 13B, the second silicide film 412b is formed with an end thereof closer to the isolation region 401 extending downward (see S_{sb}). Therefore, a distance between a bottom surface of the second source/drain region 408b and the second silicide film 412b is so small that junction leakage occurs in the second source/drain region 408b.

### SUMMARY OF THE INVENTION

In view of the above-described problems, the present invention has been achieved. An object of the present invention is to provide a semiconductor device comprising a transistor having a silicide film on a source/drain region, in which the occurrence of junction leakage is prevented.

To achieve the object, a semiconductor device according to a first aspect of the present invention includes a first MIS transistor and a second MIS transistor. The first MIS transistor includes a first gate insulating film formed on a first active region of a semiconductor substrate, a first gate electrode formed on the first gate insulating film, a first sidewall spacer formed on a side surface of the first gate electrode, a first source/drain region formed outside the first sidewall spacer in the first active region, a first silicide film formed on the first source/drain region, and a stressor insulating film formed on the first gate electrode, the first sidewall spacer, and the first silicide film, and generating a stress in a gate length direction in the first active region. The second MIS transistor includes a second gate insulating film formed on a second active region of the semiconductor substrate, a second gate electrode formed on the second gate insulating film, a second sidewall spacer formed on a side surface of the second gate electrode, a second source/drain region formed outside the second sidewall spacer in the second active region, a first protection film formed, extending over the second gate electrode, the second sidewall spacer, and a portion of the second source/drain region, and including a first protection insulating film and a second protection insulating film formed on the first protection insulating film, a second silicide film formed outside the first protection film on the second source/drain region, and the stressor insulating film formed on the first protection film and the second silicide film.

According to the semiconductor device of the first aspect of the present invention, the first protection film includes a stack of the first protection insulating film and the second protection insulating film, so that the first silicide film is formed away from a bottom surface of the first source/drain region. Therefore, it is possible to prevent the occurrence of junction leakage in the first source/drain region. In addition, the second silicide film is formed away from a bottom surface of the second source/drain region, so that junction leakage can be prevented from occurring in the second source/drain region. Therefore, it is possible to reduce power consumption of the semiconductor integrated circuit carrying the first MIS transistor and the second MIS transistor.

In the semiconductor device of the first aspect of the present invention, the semiconductor device preferably further includes a resistance device, and the resistance device preferably includes a resistor formed on an isolation region formed in the semiconductor substrate, a third sidewall spacer formed on a side surface of the resistor, a second protection film formed on the resistor and the third sidewall spacer, and including the first protection insulating film and the second protection insulating film formed on the first protection insulating film, and the stressor insulating film formed on the second protection film.

Thus, it is possible to reduce power consumption of the semiconductor integrated circuit carrying the first and second MIS transistors and the resistance device.

In the semiconductor device of the first aspect of the present invention, the first sidewall spacer preferably includes a first insulating film having an L-shaped cross-section. The second sidewall spacer preferably includes the first insulating film having the L-shaped cross-section and a second insulating film formed on the first insulating film. The third sidewall spacer preferably includes the first insulating film having the L-shaped cross-section and a second insulating film formed on the first insulating film.

In the semiconductor device of the first aspect of the present invention, the first insulating film preferably is a silicon oxide film, and the second insulating film is preferably a silicon nitride film.

In the semiconductor device of the first aspect of the present invention, the first silicide film is preferably formed away from the first sidewall spacer.

The semiconductor device of the first aspect of the present invention preferably further includes an isolation region for separating the first active region and the second active region, and a third protection film formed on at least one of a boundary region between the first active region and the isolation region and a boundary region between the second active region and the isolation region, and including the first protection insulating film and the second protection insulating film formed on the first protection insulating film.

Thus, the third protection film is provided on a boundary region between the isolation region and the first active region and/or the second active region, so that junction leakage can be prevented from occurring in the first source/drain region and/or the second source/drain region due to a treatment, such as cleaning or the like, that is performed before deposition of a silicidation metal film.

The semiconductor device of the first aspect of the present invention preferably further includes a third protection film formed on a boundary region between the second active region and an isolation region separating the second active region, and including the first protection insulating film and the second protection insulating film formed on the first protection insulating film. The third protection film is preferably integrated with the second protection film.

In the semiconductor device of the first aspect of the present invention, the first protection film is preferably formed in a region located between the second sidewall spacer and the second silicide film on the second source/drain region.

In the semiconductor device of the first aspect of the present invention, an on-gate silicide film is preferably formed on the first gate electrode, and the on-gate silicide film is preferably not formed on the second gate electrode.

In the semiconductor device of the first aspect of the present invention, an underlying insulating film is preferably formed between the second source/drain region of the semiconductor substrate and the first protection insulating film.

Thus, in the second MIS transistor, it is possible to prevent occurrence of an interface state at an interface between the second source/drain region and the first protection insulating film.

In the semiconductor device of the first aspect of the present invention, the underlying insulating film is preferably a silicon oxide film.

In the semiconductor device of the first aspect of the present invention, the first MIS transistor and the second MIS transistor preferably have the same conductivity type.

To achieve the object, a semiconductor device according to a second aspect of the present invention includes a MIS transistor and a resistance device. The MIS transistor includes a gate insulating film formed on an active region of a semiconductor substrate, a gate electrode formed on the gate insulating film, a first sidewall spacer formed on a side surface of the gate electrode, a source/drain region formed outside the first sidewall spacer in the active region, a silicide film formed on the source/drain region; and a stressor insulating film formed on the gate electrode, the first sidewall spacer, and the silicide film, and generating a stress in a gate length direction in the active region. The resistance device includes a resistor formed on an isolation region formed in the semiconductor substrate, a second sidewall spacer formed on a side surface of the resistor, a first protection film formed on the resistor and the second sidewall spacer, and including the first protection insulating film and the second protection insulating film formed on the first protection insulating film, and the stressor insulating film formed on the first protection film.

According to the semiconductor device of the second aspect of the present invention, the first protection film includes a stack of the first protection insulating film and the second protection insulating film, so that the silicide film is formed away from a bottom surface of the source/drain region. Therefore, it is possible to prevent junction leakage from occurring in the source/drain region. Therefore, it is possible to reduce power consumption of the semiconductor integrated circuit including the MIS transistor and the resistance device.

In the semiconductor device of the second aspect of the present invention, the first sidewall spacer preferably includes a first insulating film having an L-shaped cross-section, and the second sidewall spacer preferably includes the first insulating film having the L-shaped cross-section and a second insulating film formed on the first insulating film.

In the semiconductor device of the second aspect of the present invention, the first insulating film is preferably a silicon oxide film, and the second insulating film is preferably a silicon nitride film.

In the semiconductor device of the second aspect of the present invention, the silicide film is preferably formed away from the first sidewall spacer.

The semiconductor device of the second aspect of the present invention preferably further includes a second protection film formed on a boundary region between the active region and the isolation region separating the active region, and including the first protection insulating film and the second protection insulating film formed on the first protection insulating film.

Thus, the second protection film is provided on a boundary region between the isolation region and the active region, so that junction leakage can be prevented from occurring in the source/drain region due to a treatment, such as cleaning or the like, that is performed before deposition of a silicidation metal film.

To achieve the object, a method for manufacturing a semiconductor device according to an aspect of the present invention is provided. The semiconductor device includes a first MIS transistor formed in a first active region of a semiconductor substrate and a second MIS transistor formed in a second active region of the semiconductor substrate. The method includes (a) forming, on the semiconductor substrate, an isolation region for separating the first active region and the second active region, (b) forming a first gate electrode via a first gate insulating film on the first active region, and forming a second gate electrode via a second gate insulating film on the second active region, (c) forming a first sidewall spacer on a side surface of the first gate electrode, and forming a second sidewall spacer on a side surface of the second gate electrode, (d) forming a first source/drain region outside the first sidewall spacer in the first active region, and forming a second source/drain region outside the second sidewall spacer in the second active region, (e) after step (d), forming a first protection film including a first protection insulating film and a second protection insulating film formed on the first protection insulating film, on the second gate electrode, the second sidewall spacer, and a portion of the second source/drain region, (f) after step (e), forming a first silicide film outside the first sidewall spacer on the first source/drain region, and forming a second silicide film outside the first protection film on the second source/drain region, and (g) after step (f), forming a stressor insulating film on the semiconductor substrate.

According to the semiconductor device manufacturing method according to the aspect of the present invention, the first protection film including a stack of the first protection insulating film and the second protection insulating film is provided, so that the isolation region or the like is not removed when the first protection film is formed, which is different from the conventional art. Therefore, when the first and second silicide films are formed, the first and second silicide films can be formed away from bottom surfaces of the first and second source/drain regions. Therefore, junction leakage can be prevented from occurring in the first source/drain region and the second source/drain region. Therefore, it is possible to reduce power consumption of the semiconductor integrated circuit carrying the first MIS transistor and the second MIS transistor.

In the semiconductor device manufacturing method of the aspect of the present invention, step (e) preferably includes (e1) forming the first protection insulating film on the semiconductor substrate, (e2) after step (e1), forming the second protection insulating film on the first protection insulating film, (e3) after step (e2), removing portions other than portions formed on the second gate electrode, the second sidewall spacer, and the portion of the second source/drain region of the second protection insulating film, leaving the second protection insulating film on the first protection insulating film, and (e4) after step (e3), removing portions other than portions formed below the second protection insulating film of the first protection insulating film, leaving the first protection insulating film on the second gate electrode, the second sidewall spacer, and the portion of the second source/drain region.

Thus, when a predetermined portion of the second protection insulating film (note that the predetermined portion refers to portions other than portions formed on the second gate electrode, the second sidewall spacer, and a portion of the second source/drain region) is removed, since the first protection insulating film that has selectivity with respect to the second protection insulating film is formed below the second protection insulating film, the second protection insulating film is selectively removed without removing the first protection insulating film. Therefore, the first protection insulating film can prevent removal of the isolation region and the like below the first protection insulating film. Therefore, when the first and second silicide films are formed, the first and second silicide films can be formed away from bottom surfaces of the first and second source/drain regions.

In the semiconductor device manufacturing method of the aspect of the present invention, step (b) preferably includes forming a resistor on the isolation region, step (c) preferably includes forming a third sidewall spacer on a side surface of the resistor, and step (e) preferably includes forming a second protection film including the first protection insulating film and the second protection insulating film formed on the first protection insulating film, on the resistor and the third sidewall spacer.

Thus, it is possible to reduce power consumption of the semiconductor integrated circuit carrying the first and second MIS transistors and the resistance device.

In the semiconductor device manufacturing method of the aspect of the present invention, step (c) preferably includes forming the first sidewall spacer and the second sidewall spacer each including a first insulating film having an L-shaped cross-section and a second insulating film formed on the first insulating film. Step (e) preferably includes forming a protection sidewall including the first protection insulating film on a side surface of the first sidewall spacer. Step (f) preferably includes forming the first silicide film outside the protection sidewall on the first source/drain region. The method preferably further includes (h) after step (f) and before step (g), removing the second insulating film of the first sidewall spacer, and removing the protection sidewall.

Thus, before formation of the first silicide film, the protection sidewall is formed on a side surface of the first sidewall spacer, i.e., adjacent to the first sidewall spacer on the first source/drain region. Thereby, when the first silicide film is formed, it is possible to prevent silicidation of a region of the first source/drain region that is covered by the protection sidewall, so that the first silicide film can be formed outside the protection sidewall, i.e., away from the first sidewall spacer, on the first source/drain region.

Further, in this case, when the second insulating film is removed, the protection sidewall made of the first protection insulating film can also be removed, thereby making it possible to reduce an increase in manufacturing cost.

In the semiconductor device manufacturing method of the aspect of the present invention, step (c) preferably includes forming the first sidewall spacer and the second sidewall spacer each including a first insulating film having an L-shaped cross-section and a second insulating film formed on the first insulating film. The method preferably further includes (i) after step (e) and before step (f), removing the second insulating film of the first sidewall spacer.

Thus, the first and second silicide films can be formed after removal of the second insulating film. Therefore, when the second insulating film is removed, it is possible to prevent surfaces of the first and second silicide films from being removed and damaged, so that the first and second silicide films can be formed with high precision.

In the semiconductor device manufacturing method of the aspect of the present invention, step (e) preferably includes forming a third protection film including the first protection insulating film and the second protection insulating film formed on the first protection insulating film, on at least one of a boundary region between the first active region and the isolation region and a boundary region between the second active region and the isolation region.

Thus, when the first and second silicide films are formed, it is possible to prevent a boundary region between the isolation region and the first active region and/or the second active region from being removed by a treatment, such as cleaning or the like, that is performed before deposition of a silicidation metal film. Therefore, it is possible to prevent junction leakage from occurring in the first and second source/drain regions due to a treatment, such as cleaning or the like.

In the semiconductor device manufacturing method of the aspect of the present invention, step (f) preferably includes forming an on-gate silicide film on the first gate electrode.

In the semiconductor device manufacturing method of the aspect of the present invention, step (e) includes forming an underlying insulating film between the second source/drain region and the first protection insulating film.

Thus, in the second MIS transistor, it is possible to prevent an interface state from occurring at an interface between the second source/drain region and the first protection insulating film.

The semiconductor device manufacturing method of the aspect of the present invention preferably further includes (j) after step (e1) and before step (e2), performing a heat treatment for activating an impurity contained in the first source/drain region and the second source/drain region.

Thus, the heat treatment can increase a selection ratio in the first protection insulating film (e.g., a silicon nitride film) with respect to a silicon oxide film (the second protection insulating film). Therefore, when a predetermined portion of the second protection insulating film is removed, only the second protection insulating film can be removed with high precision without removing the first protection insulating film. In addition, by utilizing the heat treatment for activating the impurity contained in the first and second source/drain regions, the selection ratio in the first protection insulating film with respect to the second protection insulating film can be increased.

The semiconductor device manufacturing method of the aspect of the present invention preferably further includes (j) after step (e2) and before step (e3), performing a heat treatment for activating an impurity contained in the first source/drain region and the second source/drain region.

In the semiconductor device manufacturing method of the aspect of the present invention, step (c) preferably includes forming the first sidewall spacer, the second sidewall spacer, and the third sidewall spacer each including a first insulating film having an L-shaped cross-section and a second insulating film formed on the first insulating film. Step (e) preferably includes forming a protection sidewall including the first protection insulating film on a side surface of the first sidewall spacer. Step (f) preferably includes forming the first silicide film outside the protection sidewall on the first source/drain region. The method preferably further includes (h) after step (f) and before step (g), removing the second insulating film of the first sidewall spacer, and removing the protection sidewall.

In the semiconductor device manufacturing method of the aspect of the present invention, step (c) preferably includes forming the first sidewall spacer, the second sidewall spacer, and the third sidewall spacer each including a first insulating film having an L-shaped cross-section and a second insulating film formed on the first insulating film. The method preferably further includes (i) after step (e) and before step (f), removing the second insulating film of the first sidewall spacer.

As described above, according to the semiconductor device and its manufacturing method of the present invention, the first protection film includes a stack of the first protection insulating film and the second protection insulating film, so that the first silicide film is formed away from the bottom surface of the first source/drain region. Therefore, it is possible to prevent junction leakage from occurring in the first source/drain region. In addition, since the second silicide film is formed away from the bottom surface of the second source/drain region, it is possible to prevent junction leakage from occurring in the second source/drain region.

### BRIEF DESCRIPTION OF THE DRAWINGS

FIGS. 1A to 1C are cross-sectional views showing major steps of a method for manufacturing a semiconductor device according to a first embodiment of the present invention, in the order in which the steps are to be performed.

FIGS. 2A to 2C are cross-sectional views showing major steps of the method for manufacturing the semiconductor device of the first embodiment of the present invention, in the order in which the steps are to be performed.

FIGS. 3A and 3B are cross-sectional views showing major steps of the method for manufacturing the semiconductor device of the first embodiment of the present invention, in the order in which the steps are to be performed.

FIGS. 4A and 4B are cross-sectional views showing major steps of the method for manufacturing the semiconductor device of the first embodiment of the present invention, in the order in which the steps are to be performed.

FIG. 5 is a cross-sectional view showing a configuration of the semiconductor device of the first embodiment of the present invention.

FIGS. 6A and 6B are cross-sectional views showing major steps of a method for manufacturing a semiconductor device according to a first variation of the present invention, in the order in which the steps are to be performed.

FIGS. 7A and 7B are cross-sectional views showing major steps of a method for manufacturing a semiconductor device according to a second embodiment of the present invention, in the order in which the steps are to be performed.

FIGS. 8A and 8B are cross-sectional views showing major steps of the method for manufacturing the semiconductor device of the second embodiment of the present invention, in the order in which the steps are to be performed.

FIGS. 9A to 9C are cross-sectional views showing major steps of a method for manufacturing a conventional semiconductor device, in the order in which the steps are to be performed.

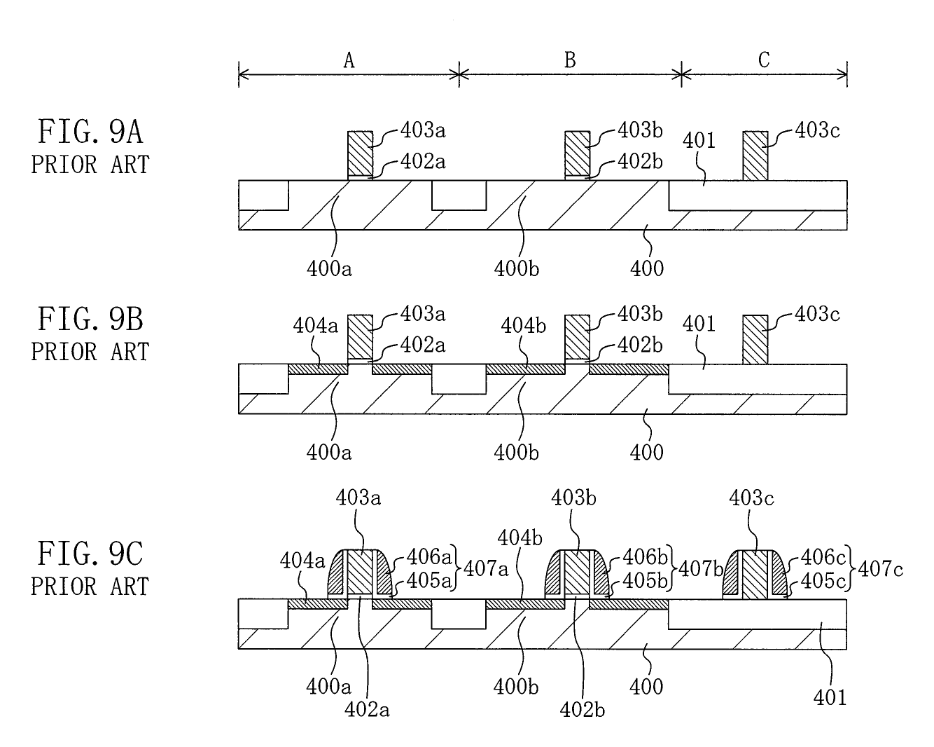

FIGS. 10A and 10B are cross-sectional views showing major steps of the method for manufacturing the conventional semiconductor device, in the order in which the steps are to be performed.

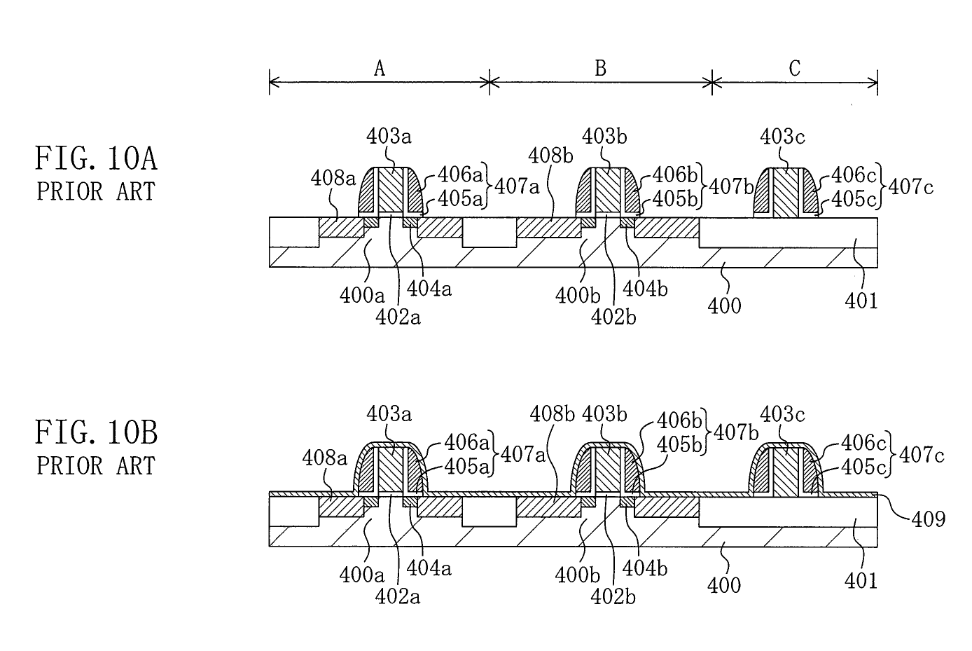

FIGS. 11A and 11B are cross-sectional views showing major steps of the method for manufacturing the conventional semiconductor device, in the order in which the steps are to be performed.

FIGS. 12A and 12B are cross-sectional views showing major steps of the method for manufacturing the conventional semiconductor device, in the order in which the steps are to be performed.

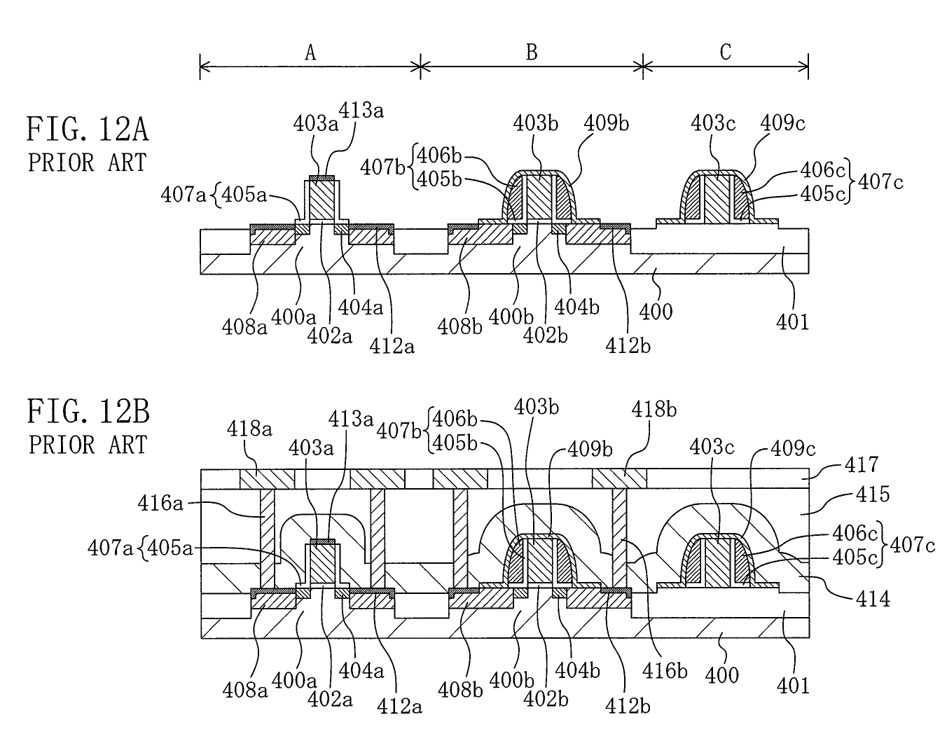

FIGS. 13A and 13B are cross-sectional views showing major steps of the conventional semiconductor device manufacturing method, indicating problems with the conventional semiconductor device.

### DETAILED DESCRIPTION OF THE PREFERRED EMBODIMENTS

Hereinafter, embodiments of the present invention will be described with reference to the accompanying drawings.

### First Embodiment

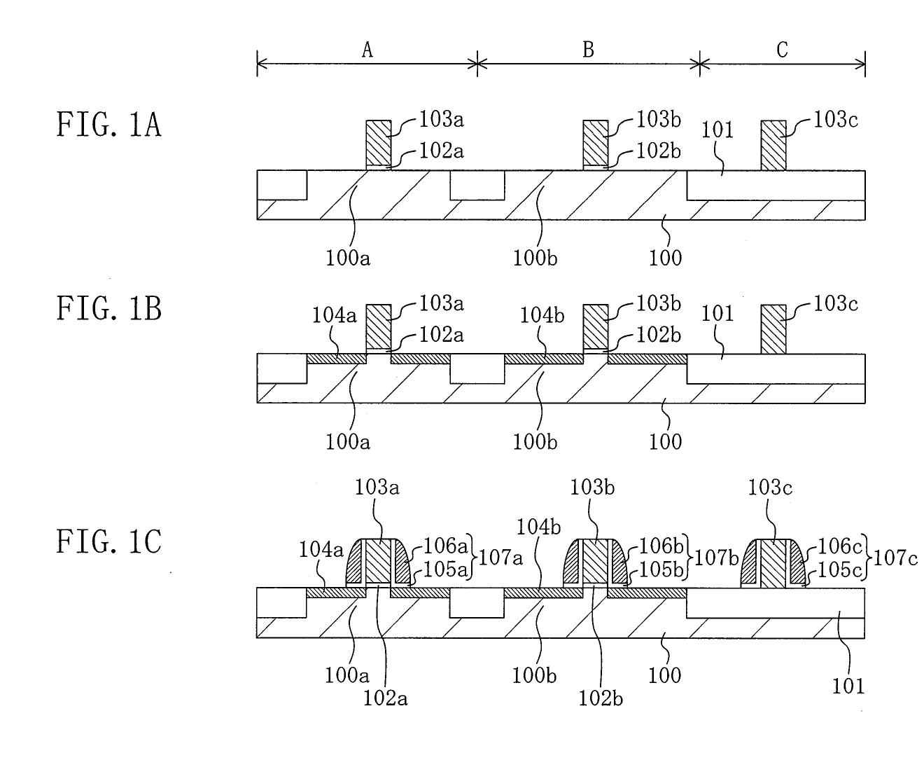

Hereinafter, a method for manufacturing a semiconductor device according to a first embodiment of the present invention will be described with reference to FIGS. 1A to 1C, FIGS. 2A to 2C, FIGS. 3A and 3B, and FIGS. 4A and 4B. FIGS. 1A to 1C, FIGS. 2A to 2C, FIGS. 3A and 3B, and FIGS. 4A and 4B are cross-sectional views showing major steps of the method for manufacturing the semiconductor device of the first embodiment of the present invention, in the order in which the steps are to be performed. Note that, in each of the figures, a first MIS transistor formation region A is shown on a left-hand side thereof, a second MIS transistor formation region B is shown in a middle thereof, and a resistance device formation region C is shown on a right-hand side thereof. Here, a first MIS transistor is a transistor for which an improvement in drive capability is required, a second MIS transistor is a transistor that is used in, for example, an ESD protection device or the like, and a resistance device is one that has a resistor made of the same material as that of gate electrodes of the first and second MIS transistors.

Initially, as shown in FIG. 1A, an isolation region 101 in which an insulating film made of a silicon oxide film is buried in a trench is selectively formed in an upper portion of a semiconductor substrate 100 made of silicon by Shallow Trench Isolation (STI). Thereby, a first active region 100a made of the semiconductor substrate 100 surrounded by the isolation region 101 is formed in the first MIS transistor formation region A, and a second active region 100b made of the semiconductor substrate 100 surrounded by the isolation region 101 is formed in the second MIS transistor formation region B.

Next, a gate insulating film formation film made of, for example, a silicon oxide film (or a silicon oxynitride film) is formed on the first and second active regions 100a and 100b, and thereafter, a gate electrode formation film made of a silicon film is formed on the semiconductor substrate 100. Thereafter, the gate electrode formation film and the gate insulating film formation film on the first and second active regions 100a and 100b are subjected to patterning to form a first and a second gate insulating film 102a and 102b made of the gate insulating film formation film, and a first and a second gate electrode 103a and 103b made of the gate electrode formation film. Also, the gate electrode formation film on the isolation region 101 in the resistance device formation region C is subjected to patterning to form a resistor 103c made of the gate electrode formation film.

Thus, as shown in FIG. 1A, the first and second gate electrodes 103a and 103b made of a silicon film are formed via the first and second gate insulating films 102a and 102b made of a silicon oxide film (or a silicon oxynitride film) on the first and second active regions 100a and 100b, and the resistor 103c made of the same material as that of the first and second gate electrodes 103a and 103b is formed on the isolation region 101 in the resistance device formation region C.

Next, as shown in FIG. 1B, an N-type impurity, such as As or the like, is implanted into the first and second active regions 100a and 100b with an energy of 2 keV using the first and second gate electrodes 103a and 103b as a mask, thereby forming a first and a second extension region 104a and 104b in a self-alignment manner outside the first and second gate electrodes 103a and 103b in the first and second active regions 100a and 100b.

Next, as shown in FIG. 1C, a first insulating film made of, for example, a silicon oxide film having a film thickness of 10 nm and a second insulating film made of, for example, a silicon nitride film having a film thickness of 40 nm are successively deposited on an entire surface of the semiconductor substrate 100, covering the first and second gate electrodes 103a and 103b, and thereafter, anisotropic dry etching is performed with respect to the first and second insulating films. Thereby, a first and a second sidewall spacer 107a and 107b including first insulating films 105a and 105b made of a silicon oxide film and having an L-shaped cross-section and second insulating films 106a and 106b made of a silicon nitride film are formed on side surfaces of the first and second gate electrodes 103a and 103b, and a third sidewall spacer 107c including a first insulating film 105c made of a silicon oxide film having an L-shaped cross-section and a second insulating film 106c made of a silicon nitride film is formed on a side surface of the resistor 103c.

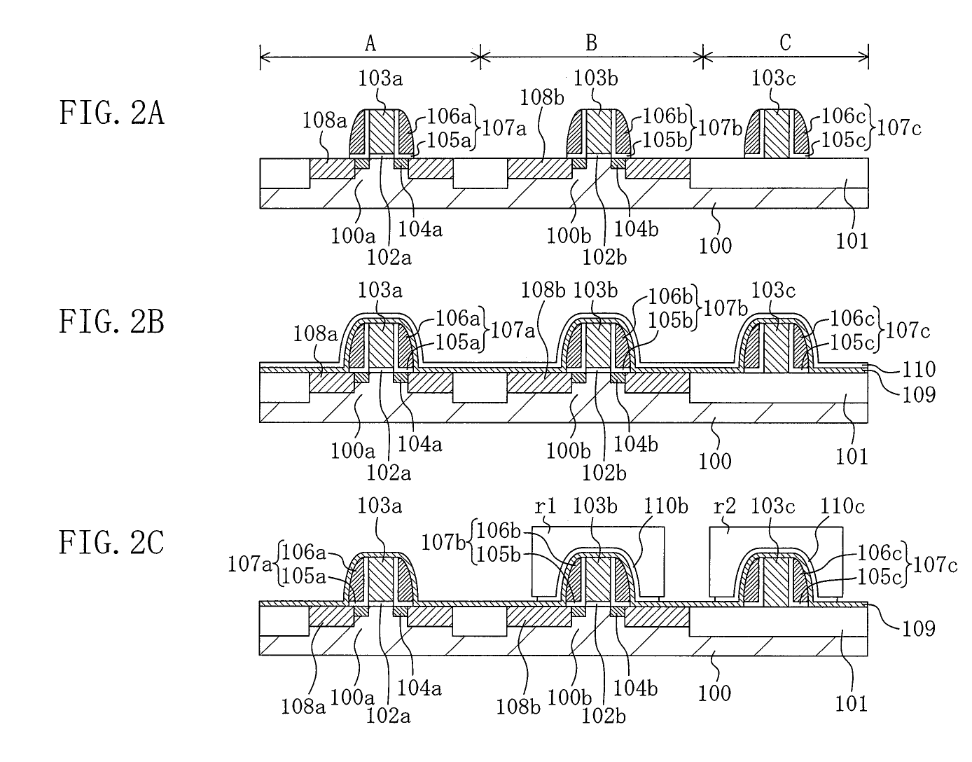

Next, as shown in FIG. 2A, an N-type impurity, such as As or the like, is implanted into the first and second active regions 100a and 100b with an energy of 15 keV, using the first and second gate electrodes 103a and 103b and the first and second sidewall spacers 107a and 107b as a mask, thereby forming a first and a second source/drain region 108a and 108b having a junction depth larger than those of the first and second extension regions 104a and 104b, in a self-alignment manner, outside the first and second sidewall spacers 107a and 107b in the first and second active regions 100a and 100b. Thereafter, the impurity contained in the first and second source/drain regions 108a and 108b is activated by a heat treatment at 1050° C.

Next, as shown in FIG. 2B, a first protection insulating film 109 made of, for example, a silicon nitride film having a film thickness of 5 nm and a second protection insulating film 110 made of, for example, a silicon oxide film having a thickness of 30 nm are deposited on an entire surface of the semiconductor substrate 100 by CVD.

Next, as shown in FIG. 2C, a resist film r1 is formed on a portion of the second protection insulating film 110 that is formed on the second gate electrode 103b, the second sidewall spacer 107b, and a portion of the second source/drain region 108b, and a resist film r2 is formed on a portion of the second protection insulating film 110 that is formed on the resistor 103c and the third sidewall spacer 107c.

Next, portions other than portions formed below the resist films r1 and r2 of the second protection insulating film 110 are removed by wet etching with hydrogen fluoride, using the resist films r1 and r2 as a mask, so that second protection insulating films 110b and 110c are left on the first protection insulating film 109. In this case, conditions for wet etching are set so as to perform over-etching, taking into consideration variations in film thickness of the second protection insulating film 110 and variations in etching rate of wet etching. Specifically, for example, when the second protection insulating film (silicon oxide film) 110 has a film thickness of 30 nm, conditions for wet etching are set so that the silicon oxide film will be removed by 36 nm.

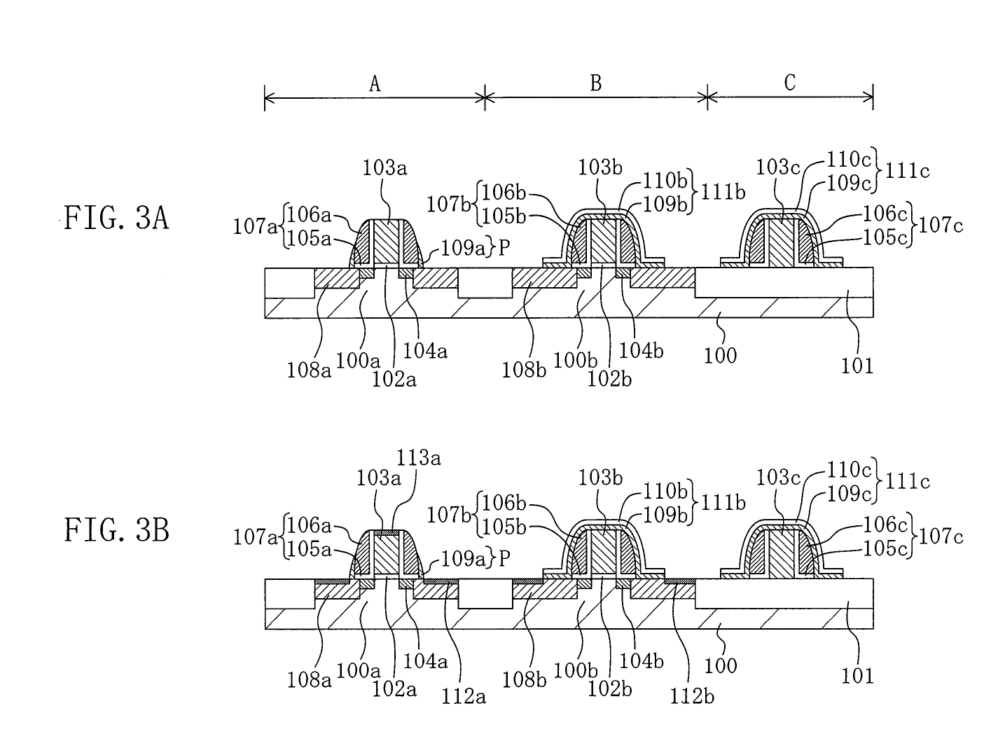

Next, as shown in FIG. 3A, after the resist films r1 and r2 are removed, anisotropic dry etching is performed with respect to the first protection insulating film 109 using the second protection insulating films 110b and 110c as a mask. Thereby, first protection insulating films 109b and 109c are left below the second protection insulating films 110b and 110c, and a first protection insulating film 109a is left on a side surface of the first sidewall spacer 107a.

Thus, a first protection film 111b which includes the first protection insulating film 109b made of the silicon nitride film having a film thickness of 5 nm and the second protection insulating film 110b made of the silicon oxide film having a film thickness of 30 nm formed on the first protection insulating film 109b, is formed on the second gate electrode 103b, the second sidewall spacer 107b and a portion of the second source/drain region 108b. Also, a second protection film 111c which includes the first protection insulating film 109c made of the silicon nitride film having a film thickness of 5 nm and the second protection insulating film 110c made of the silicon oxide film having a film thickness of 30 nm formed on the first protection insulating film 109c, is formed on the resistor 103c and the third sidewall spacer 107c. In addition, a protection sidewall P including the first protection insulating film 109a made of the silicon nitride film is formed on a side surface of the first sidewall spacer 107a.

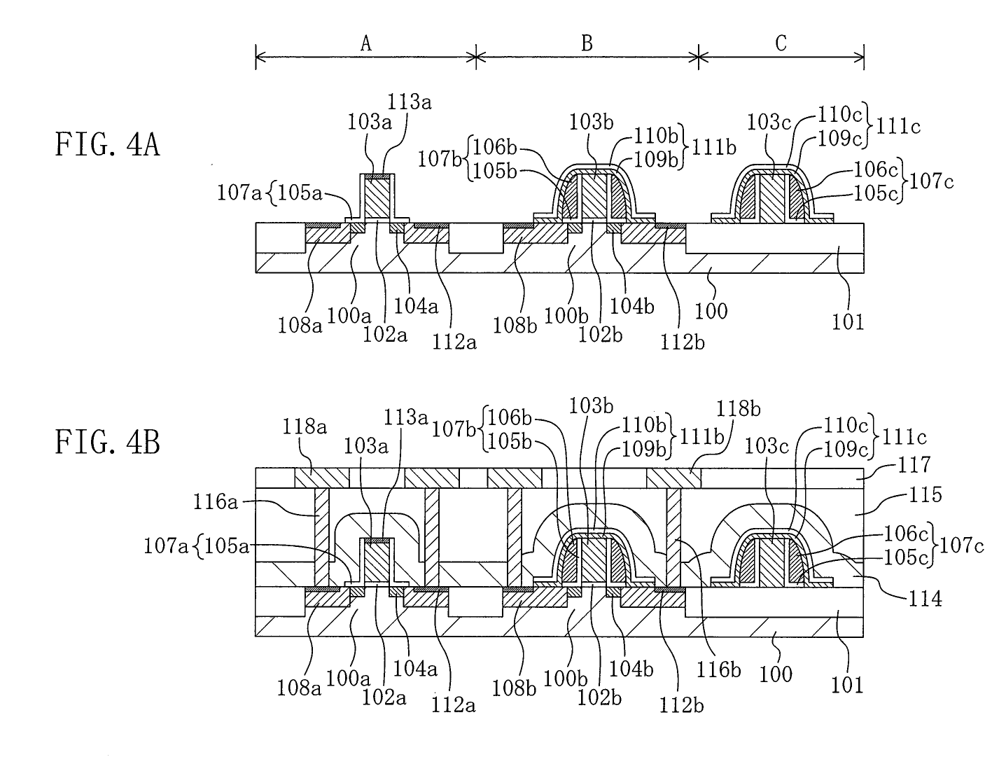

Thus, by forming the first protection film 111b on a portion of the second source/drain region 108b, a second silicide film (see 112b in FIG. 3B described below) can be formed only in a predetermined region (i.e., a region other than a region in which the first protection film 111b is formed) on the second source/drain region 108b in the next step that is a silicidation step. Here, the predetermined region includes at least a region below a second contact plug (see 116b in FIG. 4B described below) on the second source/drain region 108b.

Next, as shown in FIG. 3B, a metal film (not shown) made of, for example, a Ni film having a thickness of 10 nm is deposited by sputtering, and thereafter, a heat treatment is performed to cause reaction of Si contained in the first and second source/drain regions 108a and 108b and the first gate electrode 103a and Ni contained in the metal film. Thus, by causing reaction of an upper portion of the first source/drain region 108a and the metal film, a first silicide film 112a made of a NiSi film having a film thickness of, for example, 20 nm is formed outside the protection sidewall P on the first source/drain region 108a. Also, by causing reaction of an upper portion of the first gate electrode 103a and the metal film, an on-gate silicide film 113a made of a NiSi film having a film thickness of, for example, 20 nm is formed on the first gate electrode 103a. On the other hand, by causing reaction of an upper portion of the second source/drain region 108b and the metal film, a second silicide film 112b made of a NiSi film having a film thickness of, for example, 20 nm is formed outside the first protection film 111b on the second source/drain region 108b. Thereafter, an unreacted metal film remaining on the semiconductor substrate 100 is removed by wet etching.

Next, as shown in FIG. 4A, the second insulating film 106a made of the silicon nitride film of the first sidewall spacer 107a and the protection sidewall P made of a silicon nitride film are selectively removed by dry etching, or wet etching with hot phosphoric acid, leaving the silicon oxide film whose surface is exposed (the first and second protection insulating films 110b and 110c and the isolation region 101) and the NiSi film (the first and second silicide films 112a and 112b and the on-gate silicide film 113a).

Next, as shown in FIG. 4B, a stressor insulating film 114 made of, for example, a SiN film is formed on an entire surface of the semiconductor substrate 100. Here, the stressor insulating film 114 is an insulating film that generates a tensile stress in a gate length direction in the first active region 100a.

Thereafter, as in a method for manufacturing a typical semiconductor device having a MIS transistor, an inter-layer insulating film 115 is deposited on the stressor insulating film 114 by CVD, and thereafter, a first and a second contact plug 116a and 116b that are connected to the first and second silicide films 112a and 112b are formed in the stressor insulating film 114 and the inter-layer insulating film 115. Thereafter, an inter-wiring insulating film 117 is formed on the inter-layer insulating film 115, and thereafter, a first and a second wiring 118a and 118b that are connected to the first and second contact plugs 116a and 116b are formed in the inter-wiring insulating film 117.

Thus, the semiconductor device of the first embodiment of the present invention can be manufactured.

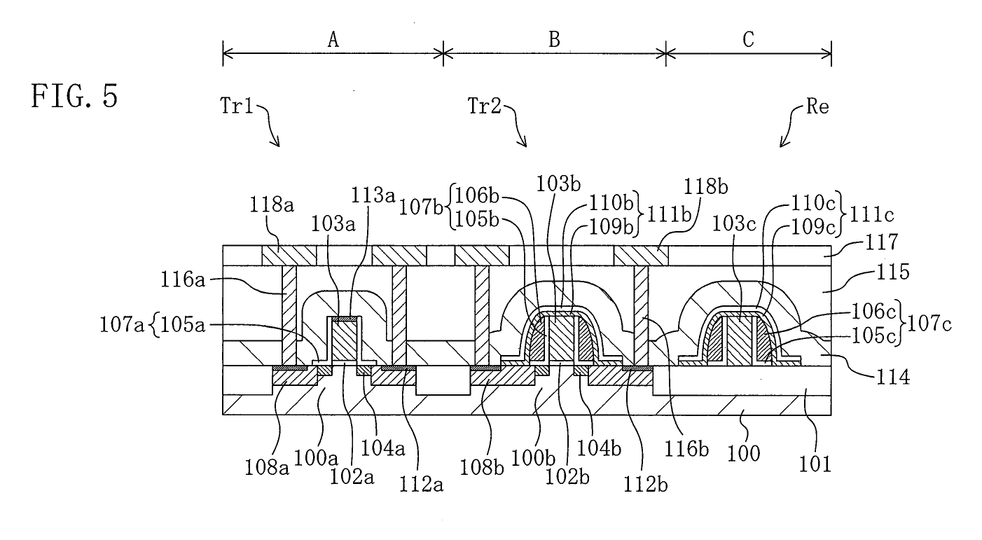

Hereinafter, a configuration of the semiconductor device of the first embodiment of the present invention will be described with reference to FIG. 5. FIG. 5 is a cross-sectional view showing the configuration of the semiconductor device of the first embodiment of the present invention. Note that, in the figure, the first MIS transistor formation region A is shown on a left-hand side thereof, the second MIS transistor formation region B is shown in a middle thereof, and the resistance device formation region C is shown on a right-hand side thereof.

As shown in FIG. 5, the isolation region 101 that is an insulating film buried in a trench is formed in an upper portion of the semiconductor substrate 100 to separate the first active region 100a and the second active region 100b. The semiconductor device comprises a first MIS transistor Tr1 provided in the first active region 100a, a second MIS transistor Tr2 provided in the second active region 100b, and a resistance device Re.

Here, as shown in FIG. 5, the first MIS transistor Tr1 comprises the first gate insulating film 102a formed on the first active region 100a, the first gate electrode 103a formed on the first gate insulating film 102a, the first sidewall spacer 107a (i.e., the first sidewall spacer from which the second insulating film 106a has been removed) formed on a side surface of the first gate electrode 103a and made of the first insulating film having an L-shaped cross-section, the first extension region 104a formed outside the first gate electrode 103a in the first active region 100a, the first source/drain region 108a formed outside the first sidewall spacer 107a in the first active region 100a, the first silicide film 112a formed on the first source/drain region 108a and spaced apart from the first sidewall spacer 107a, the on-gate silicide film 113a formed on the first gate electrode 103a, and the stressor insulating film 114 formed on the first gate electrode 103a, the first sidewall spacer 107a and the first silicide film 112a that generates a stress in a gate length direction in the first active region 100a.

On the other hand, as shown in FIG. 5, the second MIS transistor Tr2 comprises the second gate insulating film 102b formed on the second active region 100b, the second gate electrode 103b formed on the second gate insulating film 102b, the second sidewall spacer 107b formed on a side surface of the second gate electrode 103b and including the first insulating film 105b and having an L-shaped cross-section and the second insulating film 106b formed on the first insulating film 105b, the second extension region 104b formed outside the second gate electrode 103b in the second active region 100b, the second source/drain region 108b formed outside the second sidewall spacer 107b in the second active region 100b, the first protection film 111b formed, extending over the second gate electrode 103b, the second sidewall spacer 107b and a portion of the second source/drain region 108b, and including the first protection insulating film 109b and the second protection insulating film 110b formed on the first protection insulating film 109b, the second silicide film 112b formed outside the first protection film 111b on the second source/drain region 108b, and the stressor insulating film 114 formed on the first protection film 111b and the second silicide film 112b.

Also, as shown in FIG. 5, the resistance device Re comprises the resistor 103c formed on the isolation region 101, the third sidewall spacer 107c formed on a side surface of the resistor 103c and including the first insulating film 105c having an L-shaped cross-section and the second insulating film 106c formed on the first insulating film 105c, the second protection film 111c formed on the resistor 103c and the third sidewall spacer 107c and including the first protection insulating film 109c and the second protection insulating film 110c formed on the first protection insulating film 109c, and the stressor insulating film 114 formed on the second protection film 111c.

The inter-layer insulating film 115 is formed on the stressor insulating film 114. The first and second contact plugs 116a and 116b that are electrically connected via the first and second silicide films 112a and 112b to the first and second source/drain regions 108a and 108b, are formed in the stressor insulating films 114 and the inter-layer insulating film 115. The inter-wiring insulating film 117 is formed on the inter-layer insulating film 115. The first and second wirings 118a and 118b that are electrically connected to the first and second contact plugs 116a and 116b are formed in the inter-wiring insulating film 117.

According to the first embodiment, when a predetermined portion (i.e., portions other than portions formed below the resist films r1 and r2) of the second protection insulating film 110 is removed (see FIG. 2C), only the second protection insulating film 110 is selectively removed while the first protection insulating film 109 is not removed and can prevent removal of the first insulating film 105a, the isolation region 101 and the like below the first protection insulating film 109. This is because the silicon nitride film (first protection insulating film) 109 having a large selection ratio with respect to the silicon oxide film is formed below the second protection insulating film (silicon oxide film) 110.

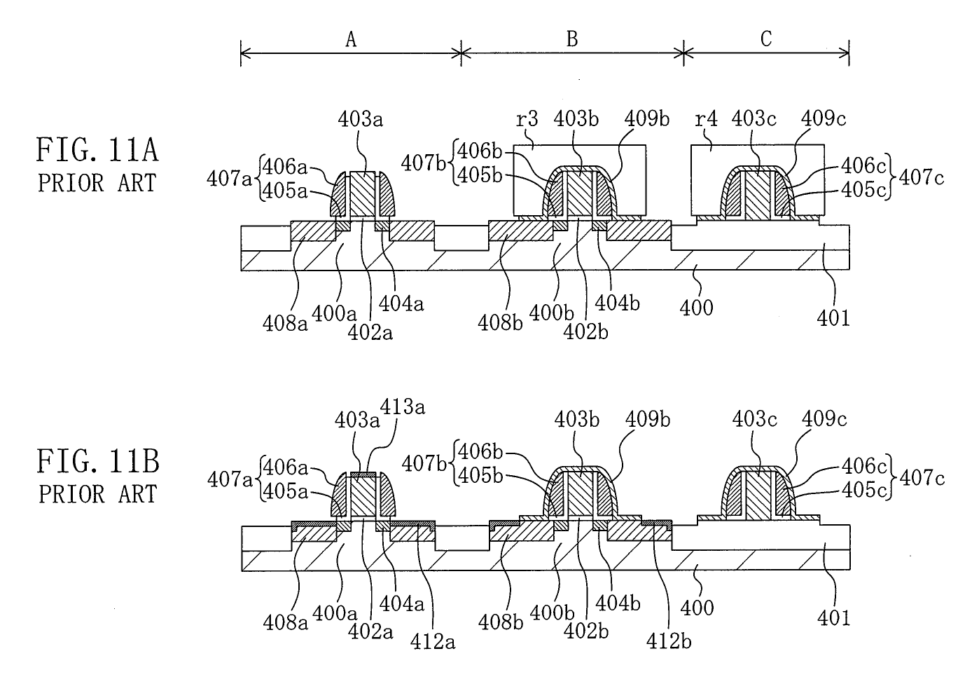

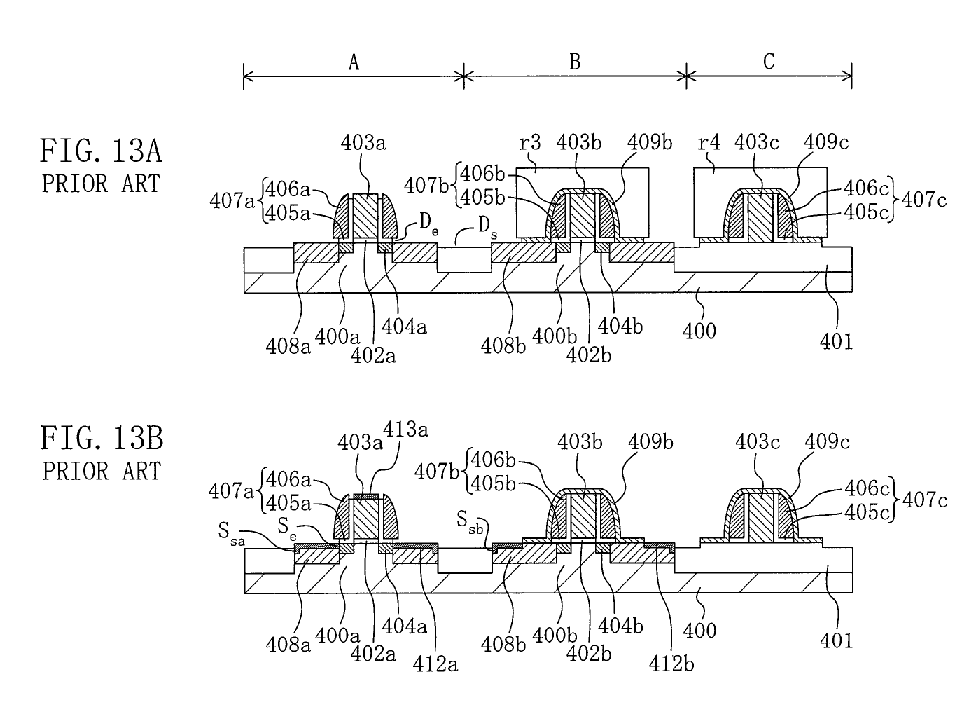

In other words, it is possible to avoid a conventional situation in which when a predetermined portion (i.e., portions other than portions formed below the resist films r3 and r4) of the protection film 409 is removed (see FIG. 11A described above), the first insulating film (silicon oxide film) 405a and the isolation region (silicon oxide film) 401 are removed to form grooves (see De and Ds in FIG. 13A described above).

Therefore, it is possible to avoid a conventional situation in which, in a silicidation step (see FIG. 11B described above), the first silicide film 412a is formed with one end thereof being formed below the second insulating film 406a (see Sₑ in FIG. 13B: described above) and the other end thereof extending downward (see Sₛₐ in FIG. 13B described above). In addition, it is possible to prevent an end portion closer to the isolation region 401 of the second silicide film 412b from extending downward (see S_{sb} in FIG. 13B described above).

Therefore, the first silicide film 112a can be formed away from a bottom surface of the first extension region 104a and a bottom surface of the first source/drain region 108a, so that junction leakage can be prevented from occurring in the first extension region 104a and the first source/drain region 108a. In addition, the second silicide film 112b can be formed away from a bottom surface of the second source/drain region 108b, so that junction leakage can be prevented from occurring in the second source/drain region 108b. Therefore, the power consumption of the semiconductor integrated circuit carrying the first MIS transistor, the second MIS transistor, and the resistance device can be reduced.

Also, according to the first embodiment, the first protection insulating film 109 is made of a silicon nitride film and the second protection insulating film 110 is made of a silicon oxide film. The selectivity between the silicon nitride film and the silicon oxide film in wet etching is typically high. Therefore, if the first protection insulating film 109 having a film thickness of 5 nm is only provided below the second protection insulating film 110 having a film thickness of 30 nm, a predetermined portion of the second protection insulating film 110 can be removed by wet etching (see FIG. 2C), leaving the first protection insulating film 109. Therefore, the film thickness of the first protection insulating film 109 can be set to be small.

In addition, according to the first embodiment, by providing the protection sidewall P adjacent to the first sidewall spacer 107a on the first source/drain region 108a as shown in FIG. 3A before the silicidation step of FIG. 3B, it is possible to prevent a region covered by the protection sidewall P of the first source/drain region 108a from undergoing silicidation in the silicidation step. Therefore, as shown in FIG. 3B, the first silicide film 112a is formed outside the protection sidewall P on the first source/drain region 108a, but not directly below the protection sidewall P. Therefore, the first silicide film 112a can be formed further away from the bottom surface of the first extension region 104a, so that the occurrence of junction leakage in the first extension region 104a can be further prevented.

Further, according to the first embodiment, if the first protection insulating film 109 is made of the same material (e.g., a silicon nitride film) as that of the second insulating film 106a, then when the second insulating film 106a is removed (FIG. 4A), the protection sidewall P made of the first protection insulating film 109a can also be removed. Thereby, an increase in manufacturing cost can be suppressed.

Also, according to the first embodiment, by removing the second insulating film 106a and the protection sidewall P (FIG. 4A) before formation of the stressor insulating film 114 (FIG. 4B), the stressor insulating film 114 can be formed on the first gate electrode 103a, the first sidewall spacer 107a (specifically, the first sidewall spacer from which the second insulating film 106a has been removed), and the first silicide film 112a. As a result, a thickness of the stressor insulating film 114 can be increased and a distance between the stressor insulating film 114 and the channel of the first MIS transistor can be reduced, in an amount corresponding to a removal amount of the second insulating film 106a and the protection sidewall P. Therefore, by the stressor insulating film 114, a tensile stress can be effectively applied in a gate length direction in the channel of the first MIS transistor, so that the mobility of carriers in the channel can be effectively improved, thereby making it possible to effectively improve the drive capability of the first MIS transistor.

Although it has been described by way of a specific example in the first embodiment that the second insulating film 106a and the protection sidewall P are removed as shown in FIG. 4A between the silicidation step (see FIG. 3B) and the step of forming the stressor insulating film 114 (see FIG. 4B) so as to effectively obtain the effect of improving the drive capability by the stressor insulating film 114, the present invention is not limited to this.

For example, after the first and second silicide films 112a and 112b and the on-gate silicide film 113a are formed, a stressor insulating film may be formed without removing the second insulating film 106a and the protection sidewall P. In this case, the stressor insulating film is formed on the first gate electrode 103a, the first sidewall spacer 107a including the first insulating film 105a and the second insulating film 106a, the protection sidewall P, and the first silicide film 112a. In other words, the stressor insulating film is formed via the second insulating film 106a and the protection sidewall P on the first gate electrode 103a, the first insulating film 105a, and the first silicide film 112a. Therefore, the effect of improving the drive capability by the stressor insulating film is relatively low, but is still sufficient, so that the drive capability of the first MIS transistor can be improved.

Although it has been described by way of a specific example in the first embodiment that, after formation of the first and second source/drain regions 108a and 108b (see FIG. 2A), a heat treatment is performed to activate an impurity contained in the first and second source/drain regions 108a and 108b, and thereafter, the first protection insulating film 109 and the second protection insulating film 110 are successively formed (FIG. 2B), the present invention is not limited to this.

For example, after formation of the first and second source/drain regions, a first protection insulating film may be formed, and thereafter, a heat treatment may be performed to activate the impurity contained in the first and second source/drain regions, and thereafter, a second protection insulating film may be formed. In this case, a selection ratio in the first protection insulating film (silicon nitride film) with respect to the silicon oxide film can be increased by the heat treatment, and therefore, when a predetermined portion of the second protection insulating film can be removed by wet etching (see FIG. 2C), only the silicon oxide film (second protection insulating film) can be removed with high precision without removing the first protection insulating film.

Alternatively, for example, after formation of the first and second source/drain regions, the first protection insulating film and the second protection insulating film may be successively formed, and thereafter, a heat treatment may be performed so as to activate the impurity contained in the first and second source/drain regions. In this case, by the heat treatment, a selection ratio in the second protection insulating film (silicon oxide film) with respect to the silicon nitride film can be increased. Therefore, when the second insulating film and the protection sidewall are removed by wet etching, but not by anisotropic dry etching (see FIG. 4A), only the silicon nitride film (the second insulating film and the protection sidewall) can be removed with high precision without removing the second protection insulating film.

Although it has been described by way of a specific example in the first embodiment that the first protection insulating film 109 is made of the same material as that of the second insulating film 106a so as to suppress an increase in manufacturing cost, the present invention is not limited to this. A material for the first protection insulating film 109 is employed such that the first protection insulating film 109a is also removed when the second insulating film 106a is removed as shown in FIG. 4A. In other words, the first protection insulating film 109 may be made of a material that has the same etching property as that of the second insulating film 106a.

Although it has also been described by way of a specific example in the first embodiment that the second insulating film 106a and the protection sidewall P are completely removed as shown in FIG. 4A, the present invention is not limited to this.

<First Variation>

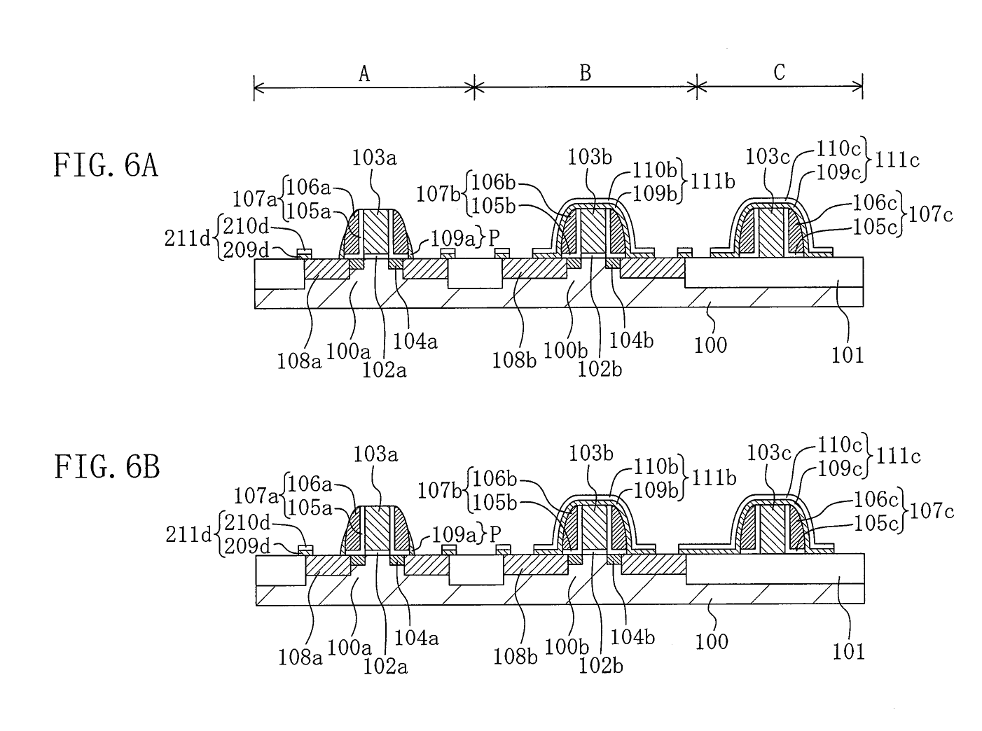

Hereinafter, a method for manufacturing a semiconductor device according to a first variation of the present invention will be described with reference to FIG. 6A. FIG. 6A is a cross-sectional view showing major steps of the method for manufacturing the semiconductor device of the first variation of the present invention. Note that, in FIG. 6A, the same components as those of the semiconductor device of the first embodiment are indicated by the same reference symbols and will not be described in detail.

In this variation, steps similar to those of FIGS. 1A to 1C and FIGS. 2A and 2B are successively performed, and thereafter, a predetermined region of the second protection insulating film 110 is removed, leaving the second protection insulating films 110b and 110c as in the first embodiment (see FIG. 2C described above). In addition, the second protection insulating film (see 210d in FIG. 6A described below) is left on a boundary region between the first active region 100a and the isolation region 101 and a boundary region between the second active region 100b and the isolation region 101.

Next, as shown in FIG. 6A, a predetermined region of the first protection insulating film 109 is removed, leaving the first protection insulating films 109a, 109b and 109c as in the first embodiment (see FIG. 3A described above), and in addition, leaving a first protection insulating film 209d below the second protection insulating film 210d.

Thus, as shown in FIG. 6A, a protection sidewall P made of the first protection insulating film 109a, a first protection film 111b made of the first protection insulating film 109b and the second protection insulating film 110b, and a second protection film 111c made of the first protection insulating film 109c and the second protection insulating film 110c are formed as in first embodiment (see FIG. 3A described above), and in addition, a third protection film 211d made of the first protection insulating film 209d and the second protection insulating film 210d is formed on a boundary region between the first active region 100a and the isolation region 101 and a boundary region between the second active region 100b and the isolation region 101.

Next, steps similar to those of FIG. 3B and FIGS. 4A and 4B described above are successively performed, so that the semiconductor device of this variation can be manufactured.

Thus, the semiconductor device of this variation comprises components similar to those of the first embodiment, and in addition, the third protection film 211d formed on the boundary region between the first active region 100a and the isolation region 101 and the boundary region between the second active region 100b and the isolation region 101 and including the first protection insulating film 209d and the second protection insulating film 210d formed on the first protection insulating film 209d (see FIG. 6A).

In the first embodiment, in the silicidation step (see FIG. 3B described above), the isolation region 101 is likely to be removed by a treatment, such as cleaning or the like, that is performed before deposition of the silicidation metal film, so that an upper surface of the isolation region 101 may be lower than upper surfaces of the first and second source/drain regions 108a and 108b, and therefore, corner portions of the first and second source/drain regions 108a and 108b may be exposed.

Thus, when the corner portions of the first and second source/drain regions 108a and 108b are exposed, a heat treatment is performed while the silicidation metal film is in contact with the corner portions of the first and second source/drain regions 108a and 108b. As a result, end portions closer to the isolation region 101 of the first and second silicide films 112a and 112b extend downward, so that junction leakage occurs in the first and second source/drain regions 108a and 108b.

To avoid this, in this variation, as shown in FIG. 6A, the third protection film 211d is provided on the boundary region between the first and second active regions 100a and 100b of the isolation region 101. Thereby, in the next step that is a silicidation step, it is possible to prevent the boundary region between the first and second active regions 100a and 100b of the isolation region 101 from being removed by a treatment, such as cleaning or the like, before deposition of a silicidation metal film. Therefore, it is possible to avoid the situation that an upper surface of the boundary region is lower than upper surfaces of the first and second source/drain regions 108a and 108b, so that the corner portions of the first and second source/drain regions 108a and 108b are exposed. Therefore, it is possible to prevent the occurrence of junction leakage in the first and second source/drain regions 108a and 108b due to a treatment, such as cleaning or the like, that is performed before deposition of a silicidation metal film.

In addition, in this variation, an effect similar to that of the first embodiment can be obtained.

Although it has been described by way of a specific example in this variation that the third protection film formed on the boundary region between the second active region 100b and the isolation region 101 is separated from the second protection film 111c as shown in FIG. 6A, the present invention is not limited to this. The third protection film may be integrated with the second protection film 111c as shown in FIG. 6B. In this case, an effect similar to that of this variation can also be obtained.

Although it also has been described by way of a specific example in this variation that the third protection film 211d is provided both on the boundary region between the first active region 100a and the isolation region 101 and on the boundary region between the second active region 100b and the isolation region 101, the present invention is not limited to this.

For example, if the third protection film is provided only on the boundary region between the first active region 100a and the isolation region 101, the third protection film can prevent the occurrence of junction leakage in the first source/drain region 108a. On the other hand, if the third protection film is provided only on the boundary region between the second active region 100b and the isolation region 101, the third protection film can prevent the occurrence of junction leakage in the second source/drain region 108b.

### Second Embodiment

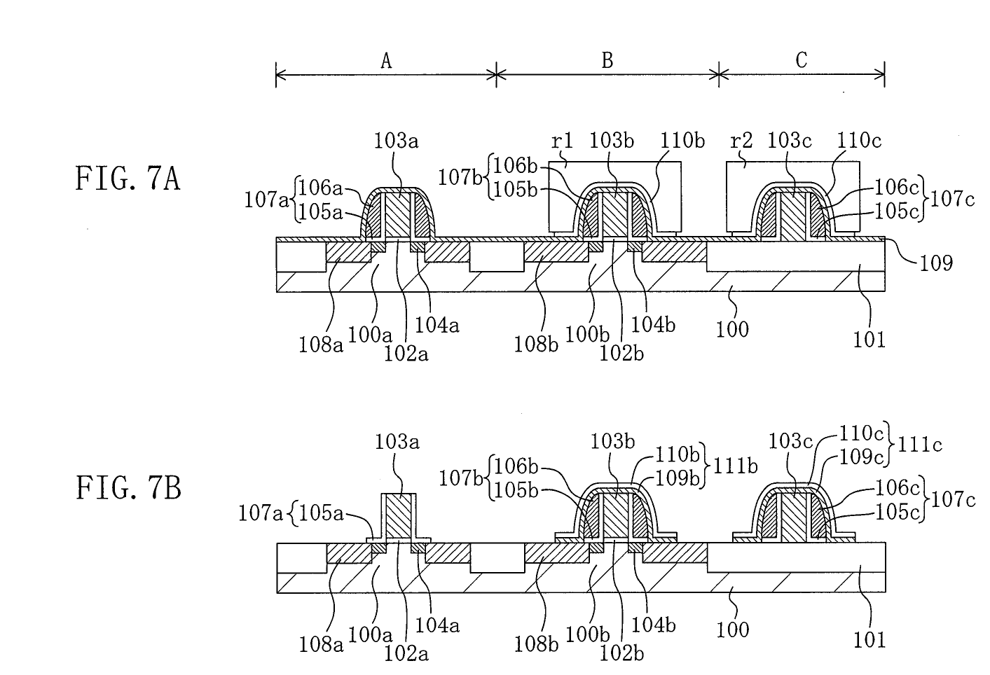

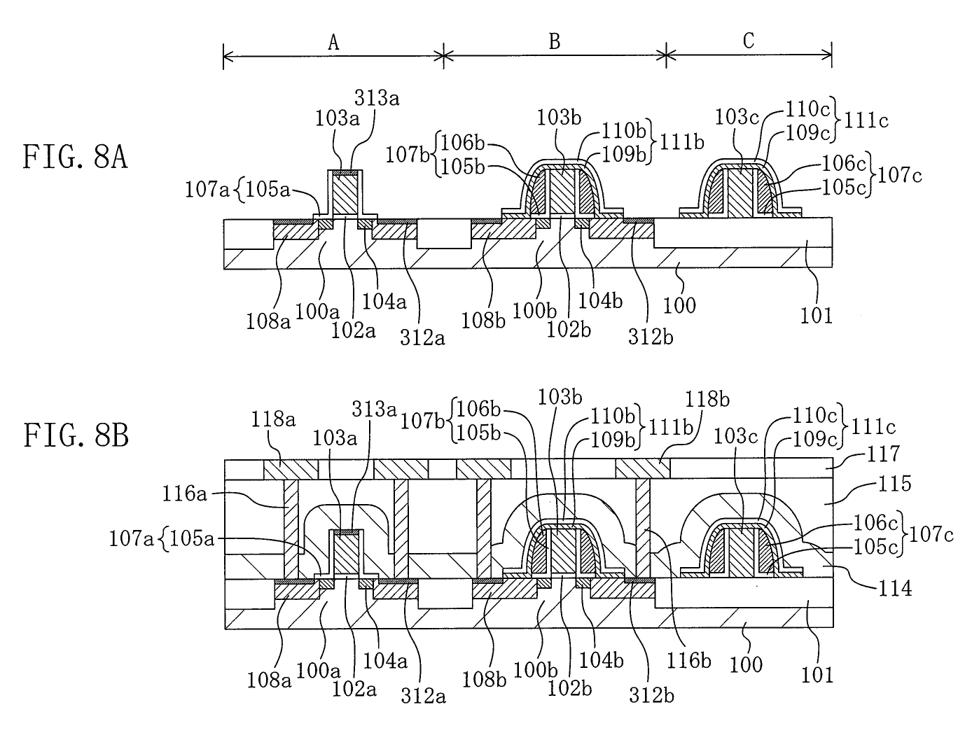

Hereinafter, a method for manufacturing a semiconductor device according to a second embodiment of the present invention will be described with reference to FIGS. 7A and 7B and FIGS. 8A and 8B. FIGS. 7A and 7B and FIGS. 8A and 8B are cross-sectional views showing major steps of the method for manufacturing the semiconductor device of the second embodiment of the present invention, in the order in which the steps are to be performed. Note that, in FIGS. 7A and 7B and FIGS. 8A and 8B, the same components as those of the semiconductor device of the first embodiment are indicated by the same reference symbols and will not be described in detail.

Initially, steps similar to those of FIGS. 1A to 1C and FIGS. 2A and 2B are successively performed.

Next, as shown in FIG. 7A, as in the step of FIG. 2C described above, by lithography, a resist film r1 is formed on a portion of the second protection insulating film that is formed on the second gate electrode 103b, the second sidewall spacer 107b, and a portion of the second source/drain region 108b, and a resist film r2 is formed on a portion of the second protection insulating film that is formed on the resistor 103c and the third sidewall spacer 107c.

Next, using the resist films r1 and r2 as a mask, portions other than portions formed below the resist films r1 and r2 of the second protection insulating film are removed by wet etching with hydrogen fluoride, leaving the second protection insulating films 110b and 110c on the first protection insulating film 109. In this case, conditions for wet etching are set so as to perform over-etching, taking into consideration variations in film thickness of the second protection insulating film and variations in etching rate of wet etching.

Next, as shown in FIG. 7B, portions other than portions formed below the second protection insulating films 110b and 110c of the first protection insulating film 109 are removed by anisotropic dry etching, or wet etching with hot phosphoric acid, using the second protection insulating films 110b and 110c as a mask, leaving the first protection insulating films 109b and 109c below the second protection insulating films 110b and 110c.

Following this, the second insulating film 106a of the first sidewall spacer 107a is removed by dry etching, or wet etching with hot phosphoric acid.

Thus, a first protection film 111b including the first protection insulating film 109b made of a silicon nitride film having a film thickness of 5 nm and a second protection insulating film 110b formed on the first protection insulating film 109b and made of a silicon oxide film having a film thickness of 30 nm, are formed on the second gate electrode 103b, the second sidewall spacer 107b, and a portion of the second source/drain region 108b. Also, a second protection film 111c including the first protection insulating film 109c made of a silicon nitride film having a film thickness of 5 nm and the second protection insulating film 110c formed on the first protection insulating film 109c and made of a silicon oxide film having a film thickness of 30 nm, are formed on the resistor 103c and the third sidewall spacer 107c.

Next, as shown in FIG. 8A, a metal film (not shown) made of, for example, a Ni film having a film thickness of 10 nm is deposited by sputtering, and thereafter, a heat treatment is performed to cause reaction of Si contained in the first and second source/drain regions 108a and 108b and the first gate electrode 103a and Ni contained in the metal film. Thus, by causing reaction of an upper portion of the first source/drain region 108a and the metal film, a first silicide film 312a made of, for example, a NiSi film having a film thickness of 20 nm is formed outside the first sidewall spacer 107a (i.e., the first sidewall spacer from which the second insulating film 106a has been removed) on the first source/drain region 108a, and by causing reaction of an upper portion of the first gate electrode 103a and the metal film, an on-gate silicide film 313a made of, for example, a NiSi film having a film thickness of 20 nm is formed on the first gate electrode 103a. On the other hand, by causing reaction of an upper portion of the second source/drain region 108b and the metal film, a second silicide film 312b made of, for example, a NiSi film having a film thickness of 20 nm is formed outside the first protection film 111b on the second source/drain region 108b. Thereafter, an unreacted metal film remaining on the semiconductor substrate 100 is removed by wet etching.

Next, as shown in FIG. 8B, as in the step of FIG. 4B described above, a stressor insulating film 114 made of, for example, a SiN film is formed on an entire surface of the semiconductor substrate 100. Here, the stressor insulating film 114 is an insulating film that generates a tensile stress in a gate length direction in the first active region 100a.

Thereafter, as in a method for manufacturing a typical semiconductor device having a MIS transistor, an inter-layer insulating film 115 is deposited on the stressor insulating film 114 by CVD, and thereafter, a first and a second contact plug 116a and 116b that are connected to the first and second silicide films 312a and 312b are formed in the stressor insulating film 114 and the inter-layer insulating film 115. Thereafter, an inter-wiring insulating film 117 is formed on the inter-layer insulating film 115, and thereafter, a first and a second wiring 118a and 118b that are connected to the first and second contact plugs 116a and 116b are formed in the inter-wiring insulating film 117.

Thus, the semiconductor device of the second embodiment can be manufactured.

Hereinafter, a difference in manufacturing method between the first embodiment and the second embodiment will be described below.

In the first embodiment, after leaving the second protection insulating films 110b and 110c (see FIG. 2C described above), anisotropic dry etching is performed with respect to the first protection insulating film 109, leaving the first protection insulating films 109b and 109c below the second protection insulating films 110b and 110c, and also leaving the protection sidewall P made of the first protection insulating film 109a on a side surface of the first sidewall spacer 107a (see FIG. 3A described above). Thereafter, the silicidation step is performed (see FIG. 3B described above), and the second insulating film 106a and the protection sidewall P are removed by dry etching or wet etching (see FIG. 4A described above).

By contrast, in the second embodiment, after leaving the second protection insulating films 110b and 110c (see FIG. 7A) as in the first embodiment, portions other than portions formed below the second protection insulating films 110b and 110c of the first protection insulating film 109 are removed by anisotropic dry etching or wet etching, leaving the first protection insulating films 109b and 109c. Following this, the second insulating film 106a is removed by dry etching or wet etching (see FIG. 7B). Thereafter, the silicidation step is performed (see FIG. 8A).

Thus, while the second insulating film 106a is removed after the silicidation step in the first embodiment, the silicidation step is performed after removal of the second insulating film 106a in the second embodiment.

Hereinafter, a configuration of the semiconductor device of the second embodiment of the present invention will be described with reference to FIG. 8B. Note that only a difference from the first embodiment will be described and similarities to the first embodiment will not be described.

Here, a difference in configuration between the first embodiment and the second embodiment will be described below.

In the first embodiment, the first silicide film 112a is formed away from the first sidewall spacer 107a on the first source/drain region 108a. In the second embodiment, the first silicide film 312a is formed outside the first sidewall spacer 107a on the first source/drain region 108a and adjacent to the first sidewall spacer 107a on the first source/drain region 108a.

According to the second embodiment, when a predetermined portion of the second protection insulating film is removed (see FIG. 7A), the first protection insulating film 109 made of a silicon nitride film having a large selection ratio with respect to a silicon oxide film is formed below the second protection insulating film (silicon oxide film) as in the first embodiment, so that junction leakage can be prevented from occurring in the first extension region 104a and the first source/drain region 108a as in the first embodiment and, in addition, in the second source/drain region 108b.

In addition, according to the second embodiment, the first protection insulating film 109 is made of the same material as that of the second insulating film 106a (e.g., a silicon nitride film). Therefore, as shown in FIG. 7B, portions other than portions formed below the second protection insulating films 110b and 110c of the first protection insulating film 109, and the second insulating film 106a can be removed in the same step, resulting in a reduction in manufacturing cost.

Further, according to the second embodiment, after removal of the second insulating film 106a (see FIG. 7B), the first and second silicide films 312a and 312b and the on-gate silicide film 313a can be formed (see FIG. 8A). Therefore, it is possible to avoid a situation in which when the second insulating film 106a (and the protection sidewall P) is removed (see FIG. 4A described above), surfaces of the first and second silicide films 112a and 112b and the on-gate silicide film 113a are removed and damaged as in the first embodiment. Therefore, as compared to the first embodiment, the first and second silicide films 312a and 312b and the on-gate silicide film 313a can be formed with high precision.

Also, according to the second embodiment, the second insulating film 106a is removed (see FIG. 7B) before the step of forming the stressor insulating film 114 (see FIG. 8B). Therefore, as shown in FIG. 8B, the stressor insulating film 114 can be formed thicker by an amount in which the second insulating film 106a has been removed, and a distance between the stressor insulating film 114 and the channel of the first MIS transistor can be reduced by such an amount. Therefore, as in the first embodiment, the drive capability of the first MIS transistor can be effectively improved.

Although it has been described by way of a specific example in the second embodiment that, in order to effectively obtain the effect of improving the drive capability due to the stressor insulating film 114, portions other than portions formed below the second protection insulating films 110b and 110c of the first protection insulating film 109 are removed as shown in FIG. 7B, and following this, the second insulating film 106a is removed, and thereafter, the silicidation step (see FIG. 8A) and the step of forming the stressor insulating film 114 (see FIG. 8B) are successively performed, the present invention is not limited to this.

For example, after portions other than portions formed below the second protection insulating films 110b and 110c of the first protection insulating film 109 are removed, the silicidation step and the stressor insulating film forming step may be successively performed without removing the second insulating film 106a. In this case, the stressor insulating film is formed via the second insulating film 106a on the first gate electrode 103a, the first insulating film 105a, and the first silicide film 312a. Therefore, although the effect of improving the drive capability due to the stressor insulating film is lower than that of the second embodiment, but is still sufficient, so that the drive capability of the first MIS transistor can be improved.

Although the semiconductor device having the configuration of FIG. 8B has been described by way of a specific example in the second embodiment, the present invention is not limited to this.

For example, as in the first variation, a third protection film (see 211d in FIG. 6A described above) formed on a boundary region between the first active region 100a and the isolation region 101 and on a boundary region between the second active region 100b and the isolation region 101 and including a first protection insulating film (see 209d in FIG. 6A described above) and a second protection insulating film (see 210d in FIG. 6A described above) may be further provided. Also in this case, as in the first variation, it is possible to prevent junction leakage from occurring in the first and second source/drain regions 108a and 108b due to a treatment, such as cleaning or the like, that is performed before deposition of a silicidation metal film.

Also, the third protection film formed on the boundary region between the second active region 100b and the isolation region 101 may be integrated with the second protection film 111c as shown in FIG. 6B described above.

Although it has been described by way of a specific example in the second embodiment that, after formation of the first and second source/drain regions (see FIG. 2A), a heat treatment is performed to activate the impurity contained in the first and second source/drain regions, and thereafter, the first protection insulating film and the second protection insulating film are successively formed (see FIG. 2B), the present invention is not limited to this.

For example, after formation of the first and second source/drain regions, the first protection insulating film may be formed, and thereafter, a heat treatment may be performed to activate the impurity contained in the first and second source/drain regions, and thereafter, the second protection insulating film may be formed. In this case, by the heat treatment, a selection ratio in the first protection insulating film (silicon nitride film) with respect to a silicon oxide film can be increased. Therefore, when a predetermined portion of the second protection insulating film is removed by wet etching (see FIG. 7A), only the silicon oxide film (second protection insulating film) can be removed with high precision without removing the first protection insulating film.

Also, for example, after formation of the first and second source/drain regions, the first protection insulating film and the second protection insulating film may be successively formed, and thereafter, a heat treatment may be performed to activate the impurity contained in the first and second source/drain regions. In this case, by the heat treatment, a selection ratio in the second protection insulating film (silicon oxide film) with respect to a silicon nitride film can be increased. Therefore, when portions other than portions formed below the second protection insulating films 110b and 110c of the first protection insulating film, and the second insulating film are removed (see FIG. 7B), only the silicon nitride film (a predetermined portion of the first protection insulating film and the second insulating film) can be removed with high precision by wet etching, but not by anisotropic dry etching, without removing the second protection insulating film.

Although it has been described by way of a specific example in the second embodiment that the first protection insulating film 109 is made of the same material as that of the second insulating film 106a so as to reduce manufacturing cost, the present invention is not limited to this. As shown in FIG. 7B, a material for the first protection insulating film 109 may be employed so that a predetermined portion of the first protection insulating film (specifically, portions other than portions formed below the second protection insulating films 110b and 110c of the first protection insulating film 109), and the second insulating film 106a are removed in the same step. In other words, the first protection insulating film 109 may be made of a material that has the same etching property as that of the second insulating film 106a.

Although it has also been described by way of a specific example in the second embodiment that the second insulating film 106a is completely removed as shown in FIG. 7B, the present invention is not limited to this.

Although it has also been described by way of a specific example in the first and second embodiments that, after formation of the first and second source/drain regions 108a and 108b (see FIG. 2A), the first protection insulating film 109 and the second protection insulating film 110 are successively formed on an entire surface of the semiconductor substrate 100 as shown in FIG. 2B, the present invention is not limited to this.

For example, after formation of the first and second source/drain regions 108a and 108b, an underlying insulating film made of a silicon oxide film having a film thickness of 1 nm may be formed on an entire surface of the semiconductor substrate 100 by, for example, ashing, plasma oxidation, or thermal oxidation, and thereafter, as in the step of FIG. 2B, the first protection insulating film 109 and the second protection insulating film 110 may be successively formed on an entire surface of the semiconductor substrate 100. In this case, the underlying insulating film (silicon oxide film) can be interposed between the second source/drain region 108b and the first protection insulating film (silicon nitride film) 109b, so that it is possible to suppress occurrence of an interface state at an interface between the second source/drain region 108b and the first protection insulating film 109b in the second MIS transistor.

Thus, although, in the first and second embodiments, the first and second protection films 111b and 111c each include a stack of two layers, i.e., the first and second protection insulating films 109b and 110b and the first and second protection insulating films 109c and 110c, respectively, the present invention is not limited to this. The first and second protection films may each include a stack of three or more layers.

Although it has been described by way of specific examples in the first and second embodiments that an N-type MIS transistor is employed as the first and second MIS transistors, the present invention is not limited to this. When a P-type MIS transistor is employed, an effect similar to this embodiment can be obtained. Note that, in this case, a stressor insulating film that generates a compressive stress in a gate length direction in the first active region 100a needs to be employed instead of the stressor insulating film 114 that generates a tensile stress in a gate length direction in the first active region 100a.

Although it has also been described by way of specific examples in the first and second embodiments that the first and second gate electrodes 103a and 103b are made of a silicon film, the present invention is not limited to this. For example, the first and second gate electrodes may be made of a metal film and a silicon film formed on the metal film. In this case, an effect similar to that of the first and second embodiments can be obtained.

Although it has also been described by way of specific examples in the first and second embodiments that a silicon oxide film (or a silicon oxynitride film) is employed as the first and second gate insulating films 102a and 102b, the present invention is not limited to this. When a high-k dielectric film is employed, an effect similar to that of the first and second embodiments can be obtained. Note that, in this case, a gate insulating film formation film made of a high-k dielectric film is formed on an entire surface of a semiconductor substrate by, for example, CVD instead of the gate insulating film formation film made of a silicon oxide film (or a silicon oxynitride film) of the first and second embodiments formed on the first and second active regions 100a and 100b, and thereafter, as in the first and second embodiments, a gate electrode formation film is formed on an entire surface of the semiconductor substrate, and thereafter, the gate insulating film formation film and the gate electrode formation film are subjected to patterning. Therefore, a gate insulating film made of the high-k dielectric film is formed between an isolation region and a resistor in a resistance device formation region.

Although it has also been described by way of specific examples in the first and second embodiment that the second protection insulating films 110b and 110c are formed on entire surfaces of the first protection insulating films 109b and 109c, the present invention is not limited to this. Particularly, when the second protection insulating films 110b and 110c are made of a silicon oxide film as in the first and second embodiments, a corner portion or an end portion of the silicon oxide films (second protection insulating films) 110b and 110c may be removed by a treatment, such as cleaning or the like, that is performed before deposition of a silicidation metal film, in the silicidation step (see FIGS. 3B and 8A), so that the second protection insulating films 110b and 110c may not be left on the entire surfaces of the first protection insulating films 109b and 109c.

Note that, as described above, the present invention can prevent the occurrence of junction leakage in a source/drain region, and therefore, is useful for a semiconductor device comprising a transistor having a silicide film on a source/drain region, and its manufacturing method.

What is claimed is:

1. A semiconductor device comprising a first MIS transistor and a second MIS transistor, wherein
the first MIS transistor includes:
a first gate insulating film formed on a first active region of a semiconductor substrate;
a first gate electrode formed on the first gate insulating film;
a first sidewall spacer formed on a side surface of the first gate electrode;
a first source/drain region formed outside the first sidewall spacer in the first active region;
a first silicide film formed on the first source/drain region; and
a stressor insulating film formed on the first gate electrode, the first sidewall spacer, and the first silicide film, wherein the stressor insulating film generates a stress in a gate length direction in the first active region, and
the second MIS transistor includes:
a second gate insulating film formed on a second active region of the semiconductor substrate;
a second gate electrode formed on the second gate insulating film;
a second sidewall spacer formed on a side surface of the second gate electrode;
a second source/drain region formed outside the second sidewall spacer in the second active region;
a first protection film formed, extending over the second gate electrode, the second sidewall spacer, and a portion of the second source/drain region, wherein the first protection film includes a first protection insulating film and a second protection insulating film formed on the first protection insulating film;
a second silicide film formed outside the first protection film on the second source/drain region; and
the stressor insulating film formed on the first protection film and the second silicide film.

2. The semiconductor device of claim 1, wherein
the semiconductor device further includes a resistance device, and
the resistance device includes:
a resistor formed on an isolation region formed in the semiconductor substrate;
a third sidewall spacer formed on a side surface of the resistor;
a second protection film formed on the resistor and the third sidewall spacer, wherein the second protection film includes the first protection insulating film and the second protection insulating film formed on the first protection insulating film; and
the stressor insulating film formed on the second protection film.

3. The semiconductor device of claim 1, wherein
the first sidewall spacer includes a first insulating film having an L-shaped cross-section, and
the second sidewall spacer includes the first insulating film having the L-shaped cross-section and a second insulating film formed on the first insulating film.

4. The semiconductor device of claim 2, wherein
the first sidewall spacer includes a first insulating film having an L-shaped cross-section, and
the second sidewall spacer and the third sidewall spacer each include the first insulating film having the L-shaped cross-section and a second insulating film formed on the first insulating film.

5. The semiconductor device of claim 3, wherein
the first insulating film is a silicon oxide film, and
the second insulating film is a silicon nitride film.

6. The semiconductor device of claim 1, wherein
the first silicide film is formed away from the first sidewall spacer.

7. The semiconductor device of claim 1, further comprising:
an isolation region for separating the first active region and the second active region; and
a third protection film formed on at least one of a boundary region between the first active region and the isolation region and a boundary region between the second active region and the isolation region, wherein the third protection film includes the first protection insulating film and the second protection insulating film formed on the first protection insulating film.

8. The semiconductor device of claim 2, further comprising:
a third protection film formed on a boundary region between the second active region and an isolation region separating the second active region, wherein the third protection film includes the first protection insulating film and the second protection insulating film formed on the first protection insulating film,
wherein the third protection film is integrated with the second protection film.

9. The semiconductor device of claim 1, wherein
the first protection film is formed in a region located between the second sidewall spacer and the second silicide film on the second source/drain region.

10. The semiconductor device of claim 1, wherein
an on-gate silicide film is formed on the first gate electrode, and
the on-gate silicide film is not formed on the second gate electrode.

11. The semiconductor device of claim 1, wherein
an underlying insulating film is formed between the second source/drain region of the semiconductor substrate and the first protection insulating film.

12. The semiconductor device of claim 11, wherein
the underlying insulating film is a silicon oxide film.

13. The semiconductor device of claim 1, wherein
the first MIS transistor and the second MIS transistor have the same conductivity type.

14. A semiconductor device comprising a MIS transistor and a resistance device, wherein
the MIS transistor includes:
a gate insulating film formed on an active region of a semiconductor substrate;
a gate electrode formed on the gate insulating film;
a first sidewall spacer formed on a side surface of the gate electrode;
a source/drain region formed outside the first sidewall spacer in the active region;
a silicide film formed on the source/drain region; and
a stressor insulating film formed on the gate electrode, the first sidewall spacer, and the silicide film, wherein the stressor insulating film generates a stress in a gate length direction in the active region, and
the resistance device includes:
a resistor formed on an isolation region formed in the semiconductor substrate;
a second sidewall spacer formed on a side surface of the resistor;
a first protection film formed on the resistor and the second sidewall spacer, wherein the first protection film includes the first protection insulating film and the second protection insulating film formed on the first protection insulating film; and
the stressor insulating film formed on the first protection film.

15. The semiconductor device of claim 14, wherein
the first sidewall spacer includes a first insulating film having an L-shaped cross-section, and
the second sidewall spacer includes the first insulating film having the L-shaped cross-section and a second insulating film formed on the first insulating film.

16. The semiconductor device of claim 15, wherein
the first insulating film is a silicon oxide film, and
the second insulating film is a silicon nitride film.

17. The semiconductor device of claim 14, wherein
the silicide film is formed away from the first sidewall spacer.

18. The semiconductor device of claim 14, further comprising:
a second protection film formed on a boundary region between the active region and the isolation region separating the active region, wherein the second protection film includes the first protection insulating film and the second protection insulating film formed on the first protection insulating film.

19. A method for manufacturing a semiconductor device, wherein the semiconductor device comprises a first MIS transistor formed in a first active region of a semiconductor substrate and a second MIS transistor formed in a second active region of the semiconductor substrate, the method comprising:
(a) forming, in the semiconductor substrate, an isolation region for separating the first active region and the second active region;
(b) forming a first gate electrode via a first gate insulating film on the first active region, and forming a second gate electrode via a second gate insulating film on the second active region;
(c) forming a first sidewall spacer on a side surface of the first gate electrode, and forming a second sidewall spacer on a side surface of the second gate electrode;
(d) forming a first source/drain region outside the first sidewall spacer in the first active region, and forming a second source/drain region outside the second sidewall spacer in the second active region;
(e) after step (d), forming a first protection film including a first protection insulating film and a second protection insulating film formed on the first protection insulating film, on the second gate electrode, the second sidewall spacer, and a portion of the second source/drain region;
(f) after step (e), forming a first silicide film outside the first sidewall spacer on the first source/drain region, and forming a second silicide film outside the first protection film on the second source/drain region; and
(g) after step (f), forming a stressor insulating film on the semiconductor substrate.

20. The method of claim 19, wherein
step (e) includes:
(e1) forming the first protection insulating film on the semiconductor substrate;
(e2) after step (e1), forming the second protection insulating film on the first protection insulating film;
(e3) after step (e2), removing portions other than portions formed on the second gate electrode, the second sidewall spacer, and the portion of the second source/drain region of the second protection insulating film, leaving the second protection insulating film on the first protection insulating film; and
(e4) after step (e3), removing portions other than portions formed below the second protection insulating film of the first protection insulating film, leaving the first protection insulating film on the second gate electrode, the second sidewall spacer, and the portion of the second source/drain region.

21. The method of claim 19, wherein
step (b) includes forming a resistor on the isolation region,
step (c) includes forming a third sidewall spacer on a side surface of the resistor, and
step (e) includes forming a second protection film including the first protection insulating film and the second protection insulating film formed on the first protection insulating film, on the resistor and the third sidewall spacer.

22. The method of claim 19, wherein
step (c) includes forming the first sidewall spacer and the second sidewall spacer each including a first insulating film having an L-shaped cross-section and a second insulating film formed on the first insulating film,
step (e) includes forming a protection sidewall including the first protection insulating film on a side surface of the first sidewall spacer,
step (f) includes forming the first silicide film outside the protection sidewall on the first source/drain region, and
the method further comprises:
(h) after step (f) and before step (g), removing the second insulating film of the first sidewall spacer, and removing the protection sidewall.

23. The method of claim 19, wherein
step (c) includes forming the first sidewall spacer and the second sidewall spacer each including a first insulating film having an L-shaped cross-section and a second insulating film formed on the first insulating film, and
the method further comprises:
(i) after step (e) and before step (f), removing the second insulating film of the first sidewall spacer.

24. The method of claim 19, wherein
step (e) includes forming a third protection film including the first protection insulating film and the second protection insulating film formed on the first protection insulating film, on at least one of a boundary region between the first active region and the isolation region and a boundary region between the second active region and the isolation region.

25. The method of claim 19, wherein
step (f) includes forming an on-gate silicide film on the first gate electrode.

26. The method of claim 19, wherein
step (e) includes forming an underlying insulating film between the second source/drain region and the first protection insulating film.

27. The method of claim 20, further comprising:
(j) after step (e1) and before step (e2), performing a heat treatment for activating an impurity contained in the first source/drain region and the second source/drain region.

28. The method of claim 20, further comprising:
(j) after step (e2) and before step (e3), performing a heat treatment for activating an impurity contained in the first source/drain region and the second source/drain region.

29. The method of claim 21, wherein
step (c) includes forming the first sidewall spacer, the second sidewall spacer, and the third sidewall spacer each including a first insulating film having an L-shaped cross-section and a second insulating film formed on the first insulating film,
step (e) includes forming a protection sidewall including the first protection insulating film on a side surface of the first sidewall spacer,
step (f) includes forming the first silicide film outside the protection sidewall on the first source/drain region, and
the method further comprises:
(h) after step (f) and before step (g), removing the second insulating film of the first sidewall spacer, and removing the protection sidewall.

30. The method of claim 21, wherein
step (c) includes forming the first sidewall spacer, the second sidewall spacer, and the third sidewall spacer each including a first insulating film having an L-shaped cross-section and a second insulating film formed on the first insulating film,
the method further comprises:
(i) after step (e) and before step (f), removing the second insulating film of the first sidewall spacer.
